(19) United States
(12) Patent Application Publication
(10) Pub. No.: US 2024/0186979 A1
(43) Pub. Date: Jun. 6, 2024

(54) ACOUSTIC WAVE DEVICE AND METHOD OF MANUFACTURING ACOUSTIC WAVE DEVICE

(71) Applicant: Murata Manufacturing Co., Ltd., Nagaokakyo-shi (JP)

(72) Inventors: Takashi YAMANE, Nagaokakyo-shi (JP); Seiji KAI, Nagaokakyo-shi (JP)

(21) Appl. No.: 18/443,472

(22) Filed: Feb. 16, 2024

Related U.S. Application Data
(63) Continuation of application No. PCT/JP2022/030987, filed on Aug. 16, 2022.
(60) Provisional application No. 63/235,185, filed on Aug. 20, 2021.

(51) Int. Cl. H03H 9/10; H03H 3/02; H03H 9/02; H03H 9/05; H03H 9/17

(52) U.S. Cl. CPC H03H 9/105; H03H 3/02; H03H 9/02031; H03H 9/02157; H03H 9/02228; H03H 9/0523; H03H 9/173; H03H 9/176; H03H 2003/021

(57) ABSTRACT

An acoustic wave device includes a first substrate, a piezoelectric layer, a functional electrode on first and/or second main surfaces of the piezoelectric layer, a second substrate, and extraction electrodes. The extraction electrodes include a support portion supporting the second substrate, a through via penetrating the second substrate, a first land on a first main surface of the second substrate and electrically connected to the through via, and a second land on a second main surface of the second substrate and electrically connected to the through via. In at least one of the extraction electrodes, insulators are provided between the first main surface of the second substrate and the first land, between the second main surface of the second substrate and the second land, and between the side wall of the through via and the second substrate.

### CROSS REFERENCE TO RELATED APPLICATIONS

This application claims the benefit of priority to Provisional Application No. 63/235,185 filed on Aug. 20, 2021 and is a Continuation application of PCT Application No. PCT/JP2022/030987 filed on Aug. 16, 2022. The entire contents of each application are hereby incorporated herein by reference.

### BACKGROUND OF THE INVENTION

### 1. Field of the Invention

The present disclosure relates to acoustic wave devices and methods of manufacturing acoustic wave devices.

### 2. Description of the Related Art

Japanese Unexamined Patent Application Publication No. 2012-257019 describes an acoustic wave device.

The acoustic wave device described in Japanese Unexamined Patent Application Publication No. 2012-257019 may be covered with the substrate on the electrode and subjected to wafer-level packaging. In this case, there is a possibility that current flows with the substrate interposed between the plurality of extraction electrodes that penetrate the substrate.

### SUMMARY OF THE INVENTION

Example embodiments of the present invention reduce or prevent the flow of current between extraction electrodes.

According to an example embodiment of the present invention, an acoustic wave device includes a first substrate, a piezoelectric layer overlapping the first substrate in plan view and including a first main surface and a second main surface on an opposite side of the first main surface, a functional electrode on at least one of the first main surface of the piezoelectric layer and the second main surface of the piezoelectric layer, a second substrate including a first main surface facing the first main surface of the piezoelectric layer in a first direction and a second main surface on an opposite side, and a plurality of extraction electrodes including a support portion supporting the second substrate between the first main surface of the piezoelectric layer and the first main surface of the second substrate, a through via penetrating the second substrate, a first land on the first main surface of the second substrate and electrically connected to the through via, and a second land on the second main surface of the second substrate and electrically connected to the through via, in which, in at least one of the plurality of extraction electrodes, insulators are provided between the first main surface of the second substrate and the first land, between the second main surface of the second substrate and the second land, and between a side wall of the through via and the second substrate.

According to an example embodiment of the present invention, a method of manufacturing an acoustic wave device includes laminating a piezoelectric layer including a first main surface and a second main surface on an opposite side of the first main surface, and a functional electrode on at least one of the first main surface and the second main surface of the piezoelectric layer, in a first direction on a first substrate, laminating a first insulator and a first land on a first main surface of a second substrate including the first main surface and a second main surface on an opposite side of the first main surface, bonding the first substrate and the second substrate such that the first main surface of the piezoelectric layer and the first main surface of the second substrate face each other, forming a second insulator on at least a portion of the second main surface of the second substrate, forming a through-hole that penetrates the second substrate at a position that overlaps the first land in plan view, forming a third insulator on a second main surface of the second substrate, a side wall of the through-hole, and a surface of the first land exposed to the through-hole, removing a portion of the third insulator, and forming a through via and a second land in the through-hole and the second main surface of the second substrate after the removing the portion of the third insulator, in which, in the laminating the first insulator and the first land, the first land is laminated on the first main surface of the second substrate with the first insulator interposed therebetween, in the removing the portion of the third insulator, at least a portion of a surface of the first land on a second substrate side at a position that overlaps the through-hole is exposed in plan view, and in the forming the through via and the second land, at least one second land is formed on the second main surface of the second substrate with the third insulator interposed therebetween.

According to example embodiments of the present invention, the flow of current between the extraction electrodes can be reduced or prevented.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1A is a perspective view illustrating an acoustic wave device of a first example embodiment of the present invention.

FIG. 1B is a plan view illustrating an electrode structure of the first example embodiment of the present invention.

FIG. 2 is a cross-sectional view of a portion taken along line II-II in FIG. 1A.

FIG. 3A is a schematic cross-sectional view for explaining a Lamb wave that propagates through a piezoelectric layer of a comparative example.

FIG. 3B is a schematic cross-sectional view for explaining a bulk wave in a thickness slip primary mode, which propagates through the piezoelectric layer of the first example embodiment of the present invention.

FIG. 4 is a schematic cross-sectional view for explaining an amplitude direction of the bulk wave in the thickness slip primary mode, which propagates through the piezoelectric layer of the first example embodiment of the present invention.

FIG. 5 is an explanatory diagram illustrating an example of resonance characteristics of the acoustic wave device of the first example embodiment of the present invention.

FIG. 6 is an explanatory diagram illustrating a relationship between d/2p and a fractional band as a resonator, where p is a center-to-center distance or an average distance of the center-to-center distances between adjacent electrodes, and d is an average thickness of the piezoelectric layer, in the acoustic wave device of the first example embodiment of the present invention.

FIG. 7 is a plan view illustrating an example in which one pair of electrodes is provided in the acoustic wave device of the first example embodiment of the present invention.

FIG. 8 is a reference diagram illustrating one example of resonance characteristics of the acoustic wave device of the first example embodiment of the present invention.

FIG. 9 is an explanatory diagram illustrating a relationship between a fractional band when multiple acoustic wave resonators are configured, and a phase rotation amount of the spurious impedance normalized by about 180 degrees as a magnitude of the spurious response, in the acoustic wave device of the first example embodiment of the present invention.

FIG. 10 is an explanatory diagram illustrating a relationship of d/2p, a metallization ratio MR, and a fractional band.

FIG. 11 is an explanatory diagram illustrating a map of the fractional band with respect to Euler angles (0°, θ, ψ) of LiNbO₃ when d/p is infinitely close to 0.

FIG. 12 is a partially cutaway perspective view for explaining the acoustic wave device according to the first example embodiment of the present invention.

FIG. 13 is a plan view illustrating a portion of the acoustic wave device according to the first example embodiment.

FIG. 14 is a cross-sectional view taken along line XIV-XIV in FIG. 13.

FIG. 15 is a cross-sectional view taken along line XV-XV in FIG. 13.

FIG. 16 is an enlarged view of a region E in FIG. 14.

FIG. 17 is an enlarged view of a region F in FIG. 15.

FIG. 18 is a cross-sectional view for explaining a first substrate lamination process according to the first example embodiment of the present invention.

FIG. 19 is a cross-sectional view for explaining the first substrate lamination process according to the first example embodiment of the present invention.

FIG. 20 is a cross-sectional view for explaining the first substrate lamination process according to the first example embodiment of the present invention.

FIG. 21 is a cross-sectional view for explaining a second substrate lamination process according to the first example embodiment of the present invention.

FIG. 22 is a cross-sectional view for explaining a bonding process according to the first example embodiment of the present invention.

FIG. 23 is a cross-sectional view for explaining a second substrate thinning process according to the first example embodiment of the present invention.

FIG. 24 is a cross-sectional view for explaining a first insulator forming process according to the first example embodiment of the present invention.

FIG. 25 is an enlarged view of a region E1 in FIG. 24.

FIG. 26 is a cross-sectional view for explaining a through-hole forming process according to the first example embodiment of the present invention.

FIG. 27 is a cross-sectional view for explaining a second insulator forming process according to the first example embodiment.

FIG. 28 is a cross-sectional view for explaining an insulator removal process according to the first example embodiment of the present invention.

FIG. 29 is a schematic cross-sectional view for explaining a seed layer forming process according to the first example embodiment of the present invention.

FIG. 30 is a cross-sectional view for explaining a through electrode forming process according to the first example embodiment of the present invention.

FIG. 31 is a cross-sectional view for explaining a through electrode forming process according to the first example embodiment of the present invention.

FIG. 32 is a cross-sectional view for explaining the through electrode forming process according to the first example embodiment of the present invention.

FIG. 33 is a cross-sectional view for explaining a seed layer removal process according to the first example embodiment of the present invention.

FIG. 34 is a cross-sectional view for explaining a third insulator forming process according to the first example embodiment of the present invention.

FIG. 35 is a cross-sectional view for explaining a bump forming process according to the first example embodiment of the present invention.

FIG. 36 is a cross-sectional view for explaining a bump forming process according to the first example embodiment of the present invention.

FIG. 37 is a cross-sectional view for explaining the bump forming process according to the first example embodiment of the present invention.

FIG. 38 is a cross-sectional view illustrating an extraction electrode connected to a reference potential according to a first example of an acoustic wave device according to a second example embodiment of the present invention.

FIG. 39 is a cross-sectional view illustrating an extraction electrode connected to a reference potential according to a second example of the acoustic wave device according to the second example embodiment of the present invention.

FIG. 40 is a cross-sectional view illustrating an extraction electrode connected to a reference potential according to a third example of the acoustic wave device according to the second example embodiment of the present invention.

FIG. 41 is a circuit diagram illustrating one example of the acoustic wave device according to the second example embodiment of the present invention.

FIG. 42 is a cross-sectional view for explaining a first insulator forming process according to the second example embodiment of the present invention.

FIG. 43 is an enlarged view of a region F1 in FIG. 42.

FIG. 44 is a cross-sectional view for explaining a through-hole forming process according to the second example embodiment of the present invention.

FIG. 45 is a cross-sectional view for explaining a second insulator forming process according to the second example embodiment of the present invention.

FIG. 46 is a cross-sectional view for explaining an insulator removal process according to the second example embodiment of the present invention.

FIG. 47 is a schematic cross-sectional view for explaining a seed layer forming process according to the second example embodiment of the present invention.

FIG. 48 is a cross-sectional view for explaining a through electrode forming process according to the second example embodiment of the present invention.

FIG. 49 is a cross-sectional view for explaining the through electrode forming process according to the second example embodiment of the present invention.

FIG. 50 is a cross-sectional view for explaining the through electrode forming process according to the second example embodiment of the present invention.

FIG. 51 is a cross-sectional view for explaining a seed layer removal process according to the second example embodiment of the present invention.

FIG. 52 is a cross-sectional view for explaining a third insulator forming process according to the second example embodiment of the present invention.

FIG. 53 is a cross-sectional view for explaining the bump forming process according to the second example embodiment of the present invention.

FIG. 54 is a cross-sectional view for explaining the bump forming process according to the second example embodiment of the present invention.

FIG. 55 is a cross-sectional view for explaining the bump forming process according to the second example embodiment of the present invention.

### DETAILED DESCRIPTION OF THE EXAMPLE EMBODIMENTS

Hereinafter, example embodiments of the present invention will be described in detail based on the drawings. The present disclosure is not limited by the example embodiments. Each example embodiment described in the present disclosure is exemplary, and in modified examples and second and subsequent example embodiments in which configurations can be partially replaced or combined between different example embodiments, descriptions of matters common to the first example embodiment will be omitted, and only differences will be described. Particularly, similar advantageous actions and effects achieved by the same or similar configurations will not be repeatedly described in each example embodiment.

### First Example Embodiment

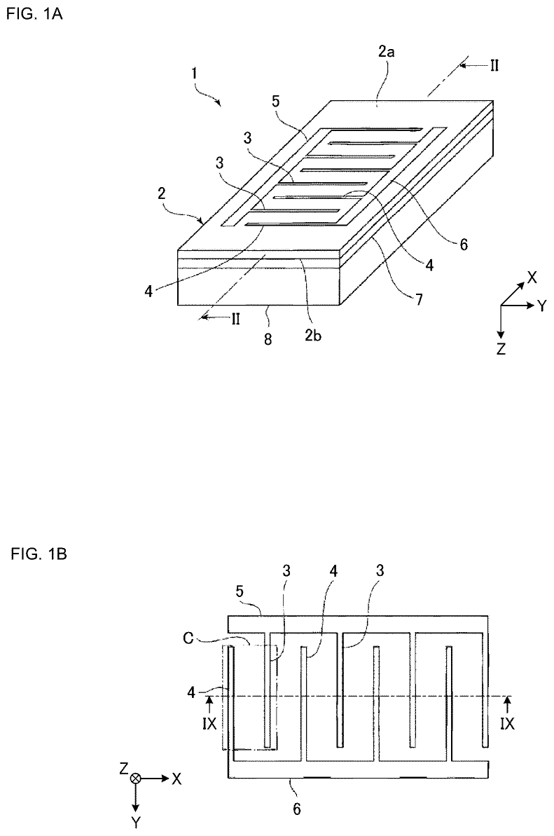

FIG. 1A is a perspective view illustrating an acoustic wave device according to a first example embodiment of the present invention. FIG. 1B is a plan view illustrating an electrode structure of the first example embodiment.

An acoustic wave device 1 of the first example embodiment includes a piezoelectric layer 2 made of, for example, LiNbO₃. The piezoelectric layer 2 may be made of, for example, LiTaO₃. The cut-angle of LiNbO₃ or LiTaO₃ is a Z cut in the first example embodiment. The cut-angle of LiNbO₃ or LiTaO₃ may be a rotational Y cut or an X cut. a propagation orientation of about ±30° for Y propagation and X propagation is preferred.

The thickness of the piezoelectric layer 2 is not particularly limited, but is preferably, for example, about 50 nm or more and about 1000 nm or less in order to effectively excite the thickness slip primary mode.

The piezoelectric layer 2 includes a first main surface 2a and a second main surface 2b that face each other in the Z direction. An electrode finger 3 and an electrode finger 4 are provided on the first main surface 2a.

Here, the electrode finger 3 is an example of the “first electrode finger” and the electrode finger 4 is an example of the “second electrode finger”. In FIGS. 1A and 1B, a plurality of electrode fingers 3 are a plurality of “first electrodes” connected to a first busbar electrode 5. The plurality of electrode fingers 4 are a plurality of “second electrodes” connected to a second busbar electrode 6. The plurality of electrode fingers 3 and the plurality of electrode fingers 4 are interdigitated with each other. As a result, an Interdigital Transducer (IDT) electrode including the electrode finger 3, the electrode finger 4, the first busbar electrode 5, and the second busbar electrode 6 is provided.

Each of the electrode fingers 3 and the electrode fingers 4 has a rectangular or substantially rectangular shape and a length direction. The electrode finger 3 and the electrode finger 4 adjacent to the electrode finger 3 face each other in a direction orthogonal or substantially orthogonal to the length direction. The length direction of the electrode fingers 3 and 4 and the direction orthogonal or substantially orthogonal to the length direction of the electrode fingers 3 and 4 are directions that intersect with the thickness direction of the piezoelectric layer 2. Therefore, it can be said that the electrode finger 3 and the electrode finger 4 adjacent to the electrode finger 3 face each other in a direction that intersects with the thickness direction of the piezoelectric layer 2. In the following description, the thickness direction of the piezoelectric layer 2 may be defined as a Z direction (or first direction), a length direction of the electrode finger 3 and the electrode finger 4 may be defined as a Y direction (or second direction), and the direction orthogonal or substantially orthogonal to the electrode finger 3 and the electrode finger 4 may be defined as an X direction (or a third direction).

Further, the length direction of the electrode finger 3 and the electrode finger 4 may be replaced with the direction orthogonal or substantially orthogonal to the length direction of the electrode finger 3 and the electrode finger 4 illustrated in FIGS. 1A and 1B. That is, in FIGS. 1A and 1B, the electrode finger 3 and the electrode finger 4 may extend in the direction in which the first busbar electrode 5 and the second busbar electrode 6 extend. In that case, the first busbar electrode 5 and the second busbar electrode 6 extend in the direction in which the electrode finger 3 and the electrode finger 4 extend in FIGS. 1A and 1B. A plurality of pairs of the electrode finger 3 connected to one potential and the electrode finger 4 connected to the other potential, which are adjacent to each other, are provided in the direction orthogonal or substantially orthogonal to the length direction of the electrode finger 3 and the electrode finger 4.

Here, the case where the electrode finger 3 and the electrode finger 4 are adjacent to each other does not indicate that the electrode finger 3 and the electrode finger 4 are in direct contact with each other, but that the electrode finger 3 and the electrode finger 4 are disposed with a gap interposed therebetween. In addition, when the electrode finger 3 and the electrode finger 4 are adjacent to each other, between the electrode finger 3 and the electrode finger 4, an electrode including other electrode fingers 3 and 4 and connected to the hot electrode or the ground electrode is not provided. The number of pairs need not be integer pairs, but may be 1.5 pairs, 2.5 pairs, or the like.

A center-to-center distance, that is, a pitch between the electrode finger 3 and the electrode finger 4 is preferably, for example, in a range of about 1 μm or more and about 10 μm or less. In addition, the center-to-center distance between the electrode finger 3 and the electrode finger 4 is a distance between the center of the width dimension of the electrode finger 3 in the direction orthogonal or substantially orthogonal to the length direction of the electrode finger 3 and the center of the width dimension of the electrode finger 4 in the direction orthogonal or substantially orthogonal to the length direction of the electrode finger 4.

Further, when at least one of the electrode finger 3 and the electrode finger 4 is a plurality of electrodes (when there are 1.5 or more electrode sets when the electrode finger 3 and the electrode finger 4 are regarded as a pair of electrode sets), the center-to-center distance of the electrode finger 3 and the electrode finger 4 indicates an average value of the center-to-center distance of each of the electrode finger 3 and the electrode fingers 4 adjacent to each other in 1.5 or more pairs of the electrode finger 3 and the electrode finger 4.

Moreover, the width of the electrode finger 3 and the electrode finger 4, that is, the dimension in the facing direction of the electrode finger 3 and the electrode finger 4 is preferably, for example, in the range of about 150 nm or more and about 1000 nm or less. In addition, the center-to-center distance between the electrode finger 3 and the electrode finger 4 is a distance between the center of the dimension (width dimension) of the electrode finger 3 in the direction orthogonal or substantially orthogonal to the length direction of the electrode finger 3 and the center of the dimension (width dimension) of the electrode finger 4 in the direction orthogonal or substantially orthogonal to the length direction of the electrode finger 4.

In the first example embodiment, since the Z-cut piezoelectric layer is used, the direction orthogonal or substantially orthogonal to the length direction of the electrode finger 3 and the electrode finger 4 is the direction orthogonal or substantially orthogonal to a polarization direction of the piezoelectric layer 2. This is not the case when a piezoelectric material with a different cut-angle is used as the piezoelectric layer 2. Here, “orthogonal” is not limited to being strictly orthogonal, but may be substantially perpendicular (an angle between the direction orthogonal to the length direction of the electrode finger 3 and the electrode finger 4 and the polarization direction is, for example, about 90°±10°).

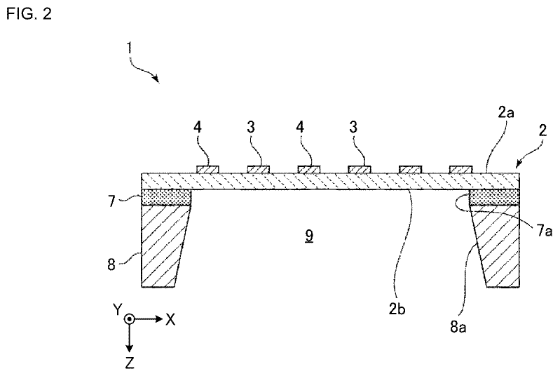

A support substrate 8 is laminated on the second main surface 2b side of the piezoelectric layer 2 with an intermediate layer 7 interposed therebetween. The intermediate layer 7 and the support substrate 8 have a frame shape and, as illustrated in FIG. 2, include cavities 7a and 8a. As a result, a space portion (air gap) 9 is provided.

The space portion 9 is provided not to disturb the vibration of an excitation region C of the piezoelectric layer 2. Therefore, the support substrate 8 is laminated on the second main surface 2b with the intermediate layer 7 interposed therebetween at a position not overlapping the portion where at least one pair of electrode finger 3 and the electrode finger 4 is provided. The intermediate layer 7 does not necessarily need to be provided. Therefore, the support substrate 8 can be directly or indirectly laminated to the second main surface 2b of the piezoelectric layer 2.

The intermediate layer 7 is made of, for example, silicon oxide. However, in addition to silicon oxide, the intermediate layer 7 can be made of appropriate insulating materials such as, for example, silicon nitride and alumina.

The support substrate 8 is made of, for example, Si. A plane orientation of the surface of Si on the piezoelectric layer 2 side may be (100) or (110), or may be (111). Preferably, high-resistance Si having a resistivity of, for example, about 4 kΩ or more is used. However, the support substrate 8 can also be made using an appropriate insulating material or semiconductor material. Examples of materials for the support substrate 8 include piezoelectric materials such as aluminum oxide, lithium tantalate, lithium niobate, and quartz crystal, various ceramics such as alumina, magnesia, sapphire, silicon nitride, aluminum nitride, silicon carbide, zirconia, cordierite, mullite, steatite, and forsterite, dielectrics such as diamond and glass, and semiconductors such as gallium nitride.

The plurality of electrode fingers 3 and 4, the first busbar electrode 5, and the second busbar electrode 6 are made of an appropriate metal or alloy such as, for example, Al or an AlCu alloy. In the first example embodiment, the electrode finger 3, the electrode finger 4, the first busbar electrode 5, and the second busbar electrode 6 include, for example, an Al film laminated on a Ti film. A close contact layer other than the Ti film may be used.

During driving, an AC voltage is applied between the plurality of electrode fingers 3 and the plurality of electrode fingers 4. More specifically, an AC voltage is applied between the first busbar electrode 5 and the second busbar electrode 6. As a result, it is possible to obtain resonance characteristics using bulk waves of the thickness slip primary mode excited in the piezoelectric layer 2.

Further, in the acoustic wave device 1, d/p is set to, for example, about 0.5 or less when d is the thickness of the piezoelectric layer 2, and p is the center-to-center distance of any of electrode fingers 3 and 4 adjacent to each other in the plurality of pairs of electrode finger 3 and electrode finger 4. As a result, the bulk waves of the thickness slip primary mode are effectively excited, and good resonance characteristics can be obtained. More preferably, for example, d/p is 0.24 or less, and in this case, even better resonance characteristics can be obtained.

When at least one of the electrode finger 3 and the electrode finger 4 is a plurality of electrode fingers as in the first example embodiment, that is, when the electrode finger 3 and the electrode finger 4 is 1.5 pairs or more in a case where the electrode finger 3 and the electrode finger 4 are regarded as one pair of electrode sets, the center-to-center distance p of the electrode finger 3 and the electrode finger 4 adjacent to each other is the average distance of the center-to-center distances between the electrode finger 3 and the electrode finger 4 adjacent to each other.

Since the acoustic wave device 1 of the first example embodiment has the above-described configuration, even when the number of pairs of the electrode finger 3 and the electrode finger 4 is reduced in order to reduce the size, a Q value is unlikely to decrease. This is because the resonance device does not require reflectors on both sides, and a propagation loss is small. The reason why the above reflector is not required is that the bulk wave of the thickness slip primary mode is used.

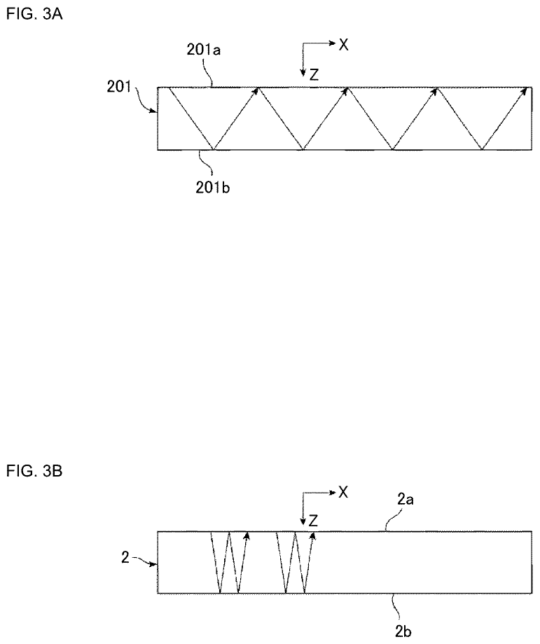

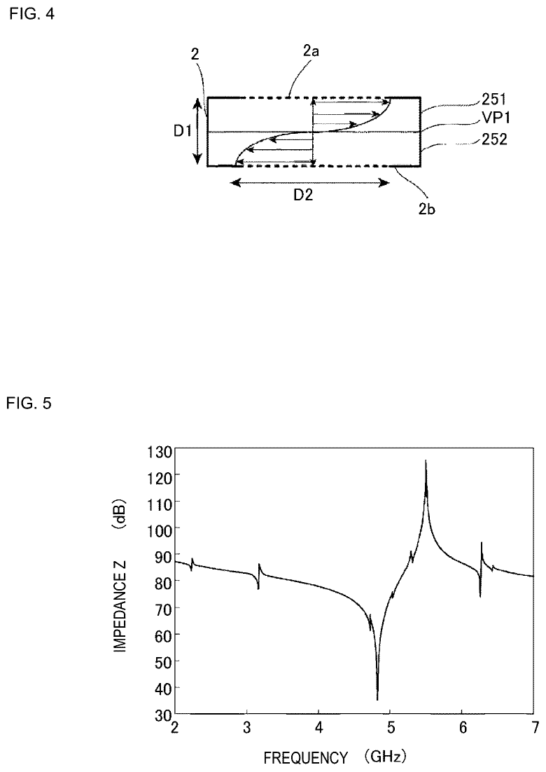

FIG. 3A is a schematic cross-sectional view for explaining a Lamb wave that propagates through a piezoelectric layer of a comparative example. FIG. 3B is a schematic cross-sectional view for explaining a bulk wave in the thickness slip primary mode, which propagates through the piezoelectric layer of the first example embodiment. FIG. 4 is a schematic cross-sectional view for explaining an amplitude direction of the bulk wave in the thickness slip primary mode, which propagates through the piezoelectric layer of the first example embodiment.

In FIG. 3A, an acoustic wave device as described in Japanese Unexamined Patent Application Publication No. 2012-257019 is illustrated, in which a Lamb wave propagates through the piezoelectric layer. As illustrated in FIG. 3A, waves propagate in the piezoelectric layer 201 as indicated by an arrow. Here, the piezoelectric layer 201 includes a first main surface 201a and a second main surface 201b, and a thickness direction connecting the first main surface 201a and the second main surface 201b is the Z direction. The X direction is a direction in which electrode fingers 3 and 4 of the IDT electrodes are arranged. As illustrated in FIG. 3A, in the Lamb wave, the wave propagates in the X direction as illustrated. Since the wave is a plate wave, although the piezoelectric layer 201 as a whole vibrates, since the wave propagates in the X direction, reflectors are disposed on both sides to obtain resonance characteristics. Therefore, when a wave propagation loss occurs and size reduction is attempted, that is, when the number of pairs of the electrode fingers 3 and 4 is decreased, the Q value decreases.

Meanwhile, as illustrated in FIG. 3B, in the acoustic wave device of the first example embodiment, since a vibration displacement is in a thickness slip direction, the wave propagates and resonates substantially in the direction connecting the first main surface 2a and the second main surface 2b of the piezoelectric layer 2, that is, in the Z direction. That is, an X-direction component of the wave is significantly smaller than a Z-direction component. Further, since resonance characteristics are obtained by propagating waves in the Z direction, no reflector is required. Therefore, no propagation loss occurs when propagating to the reflector. Therefore, even when the number of electrode pairs including the electrode finger 3 and the electrode finger 4 is reduced in an attempt to promote size reduction, the Q value is unlikely to decrease.

The amplitude directions of the bulk waves of the thickness slip primary mode are opposite to each other between a first region 251 included in the excitation region C (refer to FIG. 1B) of the piezoelectric layer 2 and a second region 252 included in the excitation region C, as illustrated in FIG. 4. FIG. 4 schematically illustrates a bulk wave when a voltage is applied between the electrode finger 3 and the electrode finger 4 such that the potential of the electrode finger 4 is higher than that of the electrode finger 3. The first region 251 is a region of the excitation region C between the first main surface 2a and a virtual plane VP1 that is orthogonal or substantially orthogonal to the thickness direction of the piezoelectric layer 2 and bisects the piezoelectric layer 2. The second region 252 is a region of the excitation region C between the virtual plane VP1 and the second main surface 2b.

In the acoustic wave device 1, at least one pair of electrodes including the electrode finger 3 and the electrode finger 4 is provided. However, since waves are not propagated in the X direction, the number of electrode pairs including the electrode finger 3 and the electrode finger 4 does not necessarily need to be plural. That is, at least one pair of electrodes may be provided.

For example, the electrode finger 3 is an electrode connected to a hot potential and the electrode finger 4 is an electrode connected to a ground potential. However, the electrode finger 3 may be connected to the ground potential and the electrode finger 4 may be connected to the hot potential. In the first example embodiment, at least one pair of electrodes is the electrode connected to the hot potential or the electrode connected to a ground potential, as described above, and no floating electrodes are provided.

FIG. 5 is an explanatory diagram illustrating an example of resonance characteristics of the acoustic wave device of the first example embodiment.

The design parameters of the acoustic wave device 1 with the resonance characteristics illustrated in FIG. 5 are as follows.

Piezoelectric layer 2: LiNbO₃ with Euler angles (0°, 0°, 90°)

Thickness of piezoelectric layer 2: about 400 nm

Length of excitation region C (refer to FIG. 1B): about 40 μm

Number of pairs of electrodes including electrode finger 3 and electrode finger 4: 21 pairs

Center-to-center distance (pitch) between electrode finger 3 and electrode finger 4: about 3 μm

Width of electrode finger 3 and electrode finger 4: about 500 nm

d/p: about 0.133

Intermediate layer 7: Silicon oxide film with a thickness of about 1 μm

Support substrate 8: Si

Further, the excitation region C (refer to FIG. 1B) is a region where the electrode finger 3 and the electrode finger 4 overlap each other when viewed in the X direction orthogonal or substantially orthogonal to the length direction of the electrode finger 3 and the electrode finger 4. The length of the excitation region C is the dimension along the length direction of the electrode finger 3 and the electrode finger 4 of the excitation region C. Here, the excitation region C is an example of an “intersecting region”.

In the first example embodiment, electrode-to-electrode distances of electrode pairs including the electrode finger 3 and the electrode finger 4 are all equal or substantially equal in the plurality of pairs. That is, the electrode finger 3 and the electrode finger 4 were disposed at equal or substantially equal pitches.

As is clear from FIG. 5, good resonance characteristics with a fractional band of about 12.5%, for example, are obtained in spite of including no reflector.

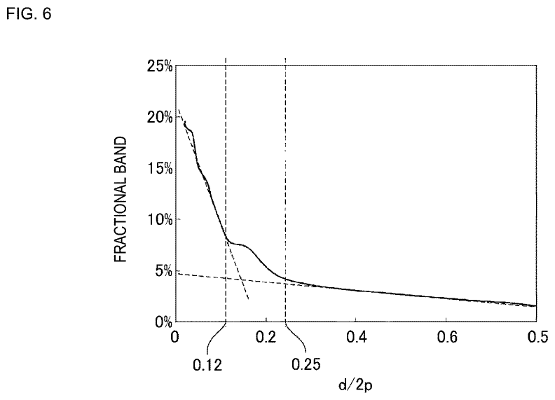

Incidentally, when d is the thickness of the piezoelectric layer 2, and p is the center-to-center distance of electrodes between the electrode finger 3 and the electrode finger 4, d/p is, for example, about 0.5 or less, and more preferably about 0.24 or less in the first example embodiment. This will be explained with reference to FIG. 6.

A plurality of acoustic wave devices were obtained by changing d/2p in the same manner as the acoustic wave device that obtained the resonance characteristics illustrated in FIG. 5. FIG. 6 is an explanatory diagram illustrating a relationship between d/2p and a fractional band as a resonator, where p is a center-to-center distance or an average distance of the center-to-center distances between adjacent electrodes, and d is an average thickness of the piezoelectric layer 2, in the acoustic wave device of the first example embodiment.

As illustrated in FIG. 6, when d/2p exceeds about 0.25, that is, when d/p>about 0.5, even when d/p is adjusted, the fractional band is less than about 5%. Meanwhile, when d/2p≤about 0.25, that is, d/p≤about 0.5, the fractional band can be increased to about 5% or more by changing d/p within that range, that is, a resonator having a high coupling coefficient can be constructed. Further, when d/2p is about 0.12 or less, that is, when d/p is about 0.24 or less, the fractional band can be increased to about 7% or more. In addition, by adjusting d/p within this range, a resonator with a wider fractional band can be obtained, and a resonator with a higher coupling coefficient can be realized. Therefore, for example, by setting d/p to about 0.5 or less, it is possible to provide a resonator having a high coupling coefficient using the bulk wave of the thickness slip primary mode.

In addition, at least one pair of electrodes may be one pair, and the p is the center-to-center distance between the electrode finger 3 and the electrode finger 4 adjacent to each other in the case of one pair of electrodes. In the case of 1.5 pairs or more of electrodes, the average distance of the center-to-center distances of the electrode finger 3 and the electrode finger 4 adjacent to each other may be defined as p.

As for the thickness d of the piezoelectric layer 2, when the piezoelectric layer 2 has variations in thickness, a value obtained by averaging the thickness may be used.

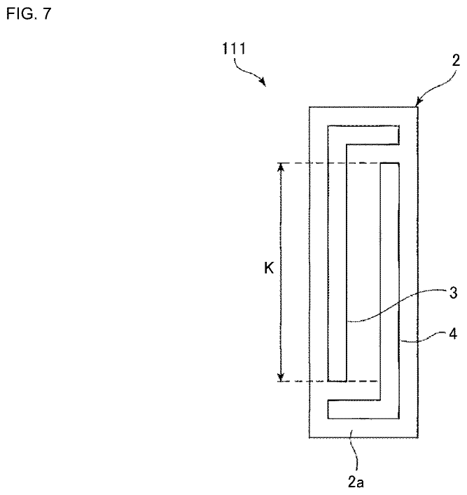

FIG. 7 is a plan view illustrating an example in which one pair of electrodes is provided in the acoustic wave device of the first example embodiment. In an acoustic wave device 101, one pair of electrodes including the electrode finger 3 and the electrode finger 4 is provided on the first main surface 2a of the piezoelectric layer 2.

K in FIG. 7 is an intersecting width. As described above, in the acoustic wave device according to the present example embodiment, the number of pairs of electrodes may be one. Even in this case, when the above d/p is about 0.5 or less, it is possible to effectively excite the bulk wave in the thickness slip primary mode.

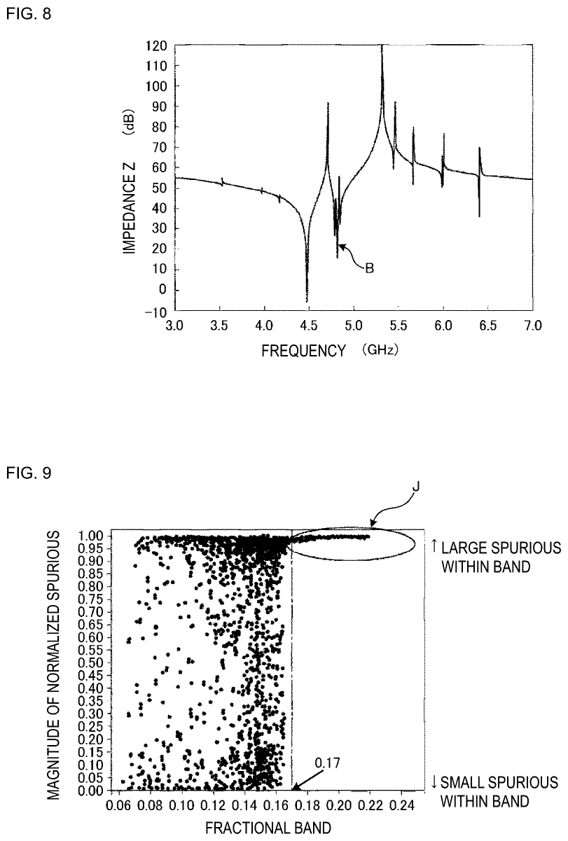

In the acoustic wave device 1, preferably, in the plurality of electrode fingers 3 and electrode fingers 4, the metallization ratio MR of the electrode finger 3 and the electrode finger 4 adjacent to each other with respect to the excitation region C, which is the region where any of the electrode finger 3 and the electrode finger 4 adjacent to each other overlap each other when viewed in the facing direction, satisfies MR about 1.75(d/p)+0.075. In that case, spurious responses can be effectively reduced. This will be described with reference to FIGS. 8 and 9.

FIG. 8 is a reference diagram illustrating one example of resonance characteristics of the acoustic wave device of the first example embodiment. A spurious response indicated by an arrow B appears between a resonant frequency and an anti-resonant frequency. As d/p=about 0.08, Euler angles of LiNbO₃ were set to (0°, 0°, 90°). In addition, the metallization ratio MR was set to about 0.35.

The metallization ratio MR will be explained with reference to FIG. 1B. In the electrode structure of FIG. 1B, when attention is paid to the pair of the electrode finger 3 and the electrode finger 4, it is assumed that only the pair of electrode finger 3 and the electrode finger 4 is provided. In this case, a portion surrounded by a dashed-dotted line is the excitation region C. The excitation region C is a region of the electrode finger 3 that overlaps the electrode finger 4, a region of the electrode finger 4 that overlaps the electrode finger 3, and a region between the electrode finger 3 and the electrode finger 4 where the electrode finger 3 and the electrode finger 4 overlap each other when the electrode finger 3 and the electrode finger 4 are viewed in the direction orthogonal or substantially orthogonal to the length direction of the electrode finger 3 and the electrode finger 4, that is, in the facing direction. An area of the electrode finger 3 and the electrode finger 4 in the excitation region C with respect to an area of this excitation region C is the metallization ratio MR. That is, the metallization ratio MR is the ratio of the area of the metallization portion with respect to the area of the excitation region C.

When the plurality of pairs of electrode fingers 3 and the electrode fingers 4 are provided, the ratio of the metallization portion included in the entire excitation region C to the total area of the excitation region C may be MR.

FIG. 9 is an explanatory diagram illustrating a relationship between a fractional band when multiple acoustic wave resonators are configured, and a phase rotation amount of the spurious impedance normalized by about 180 degrees as a magnitude of the spurious response, in the acoustic wave device of the first example embodiment. The fractional band was adjusted by variously changing the film thickness of the piezoelectric layer 2 or the dimensions of the electrode finger 3 and the electrode finger 4. Moreover, FIG. 9 illustrates the results when the piezoelectric layer 2a containing Z-cut LiNbO₃ is used, but the same tendency is obtained when piezoelectric layers 2 with other cut-angles are used.

In a region surrounded by an ellipse J in FIG. 9, the spurious response is as large as about 1.0. As is clear from FIG. 9, when the fractional band exceeds about 0.17, that is, exceeds about 17%, a large spurious response with a spurious level of about 1 or more appears in a pass band even when the parameters defining the fractional band are changed. That is, as in the resonance characteristics illustrated in FIG. 8, a large spurious response indicated by an arrow B appears within the band. Therefore, for example, the fractional band is preferably about 17% or less. In this case, by adjusting the film thickness of the piezoelectric layer 2 and the dimensions of the electrode finger 3 and the electrode finger 4, the spurious response can be reduced.

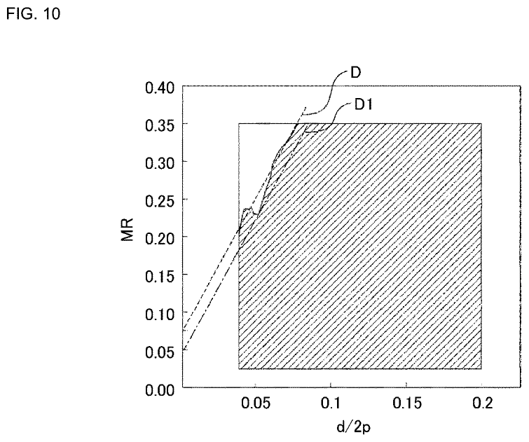

FIG. 10 is an explanatory diagram illustrating a relationship of d/2p, the metallization ratio MR, and the fractional band. In the acoustic wave device 1 of the first example embodiment, various acoustic wave devices 1 having different d/2p and MR were constructed, and the fractional band was measured. A hatched portion on a right side of a broken line D in FIG. 10 is the region where the fractional band is about 17% or less. A boundary between the hatched region and the non-hatched region is expressed by MR=about 3.5(d/2p)+0.075. That is, MR=about 1.75(d/p)+0.075. Therefore, for example, preferably, MR≤about 1.75(d/p)+0.075. In that case, it is easy to set the fractional band to about 17% or less. A region on a right side of MR=about 3.5(d/2p)+0.05 indicated by a dashed-dotted line Dl in FIG. 10 is more preferable. That is, when MR≤1.75(d/p)+0.05, the fractional band can be reliably reduced to about 17% or less.

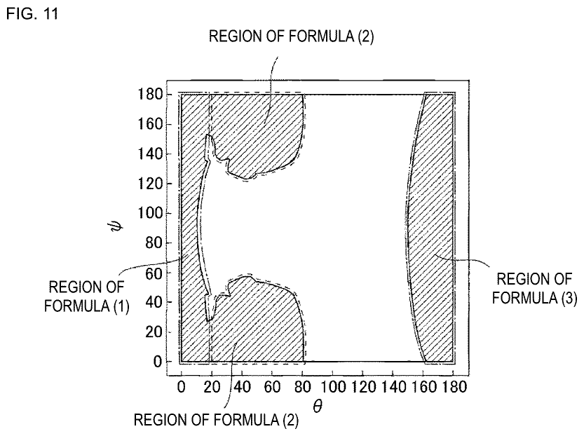

FIG. 11 is an explanatory diagram illustrating a map of the fractional band with respect to Euler angles (0°, θ, ψ) of LiNbO₃ when d/p is infinitely close to 0. The hatched portion in FIG. 11 is a region where a fractional band of at least about 5% or more is obtained. When the range of the region is approximated, the range is a range represented by Formula (1), Formula (2), and Formula (3) below.

(0°±10°,0° to 20°,any ψ) Formula (1)

(0°±10°,20° to 80°,0° to 60°(1−(θ−50)²/900)^{1/2})or(0°±10°,20° to 80°,[180°−60°(1−(θ−50)²/900)^{1/2}] to 180°) Formula (2)

(0°±10°,[180°−30°(1−(ψ−90)²/8100)^{1/2}] to 180°,any ψ) Formula (3)

Therefore, in the case of the Euler angle range of Formula (1), Formula (2), or Formula (3) described above, the fractional band can be sufficiently widened, which is preferable.

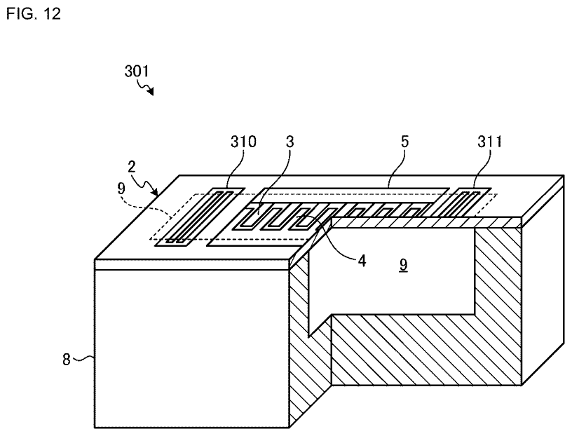

FIG. 12 is a partially cutaway perspective view for explaining the acoustic wave device according to the present example embodiment. In FIG. 12, an outer periphery of the space portion 9 is indicated by broken lines. The acoustic wave device of an example embodiment of the present invention may use a plate wave. In this case, as illustrated in FIG. 12, an acoustic wave device 301 includes reflectors 310 and 311. The reflectors 310 and 311 are provided on both sides of the electrode fingers 3 and 4 of the piezoelectric layer 2 in the acoustic wave transmission direction. In the acoustic wave device 301, a Lamb wave as a plate wave is excited by applying an AC electric field to the electrode fingers 3 and 4 on the space portion 9. Since the reflectors 310 and 311 are provided on both sides, the resonance characteristics due to the Lamb wave as a plate wave can be obtained.

As described above, in the acoustic wave devices 1 and 101, a bulk wave in the thickness slip primary mode is used. Further, in the acoustic wave devices 1 and 101, the first electrode finger 3 and the second electrode finger 4 are electrodes adjacent to each other, and d/p is set to, for example, about 0.5 or less when d is the thickness of the piezoelectric layer 2, and p is the center-to-center distance of the first electrode finger 3 and the second electrode finger 4. Accordingly, the Q value can be increased even when the acoustic wave device is reduced in size.

In the acoustic wave devices 1 and 101, the piezoelectric layer 2 is made of, for example, lithium niobate or lithium tantalate. It is preferable that the first main surface 2a or the second main surface 2b of the piezoelectric layer 2 is provided with the first electrode finger 3 and the second electrode finger 4 facing each other in the direction that intersects with the thickness direction of the piezoelectric layer 2, and the first electrode finger 3 and the second electrode finger 4 is covered with a protective film.

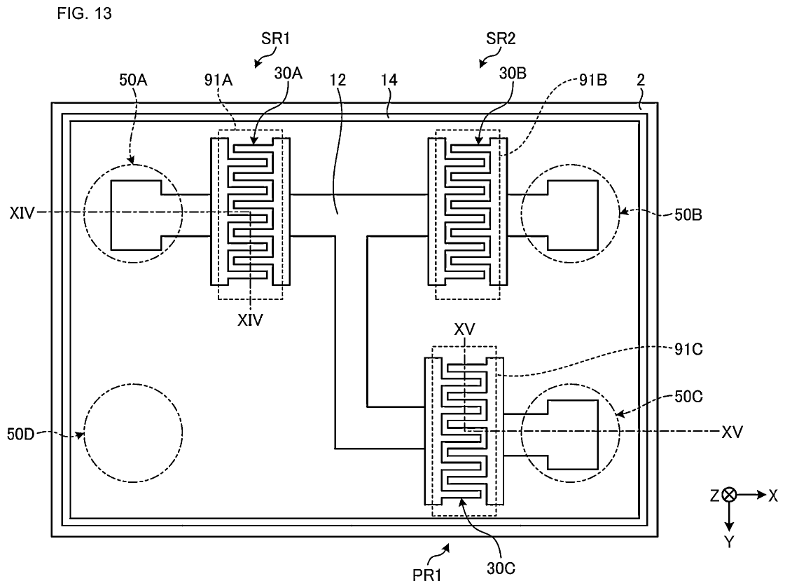

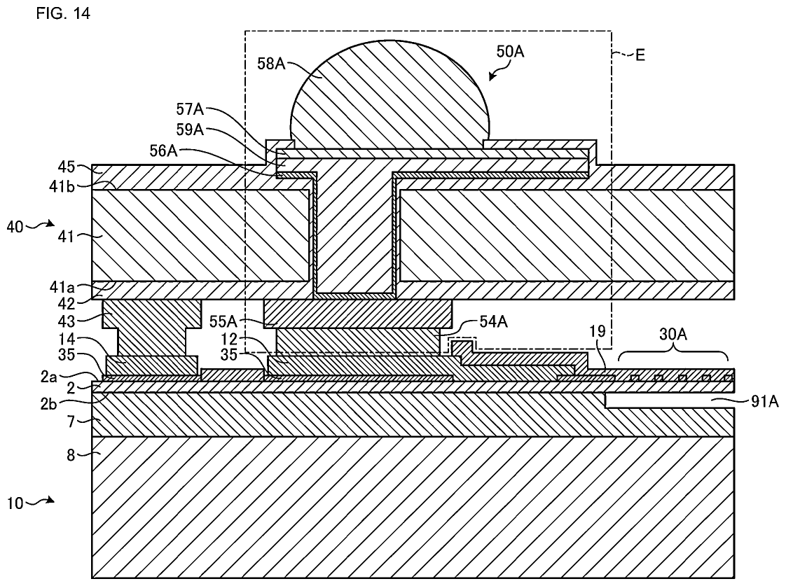

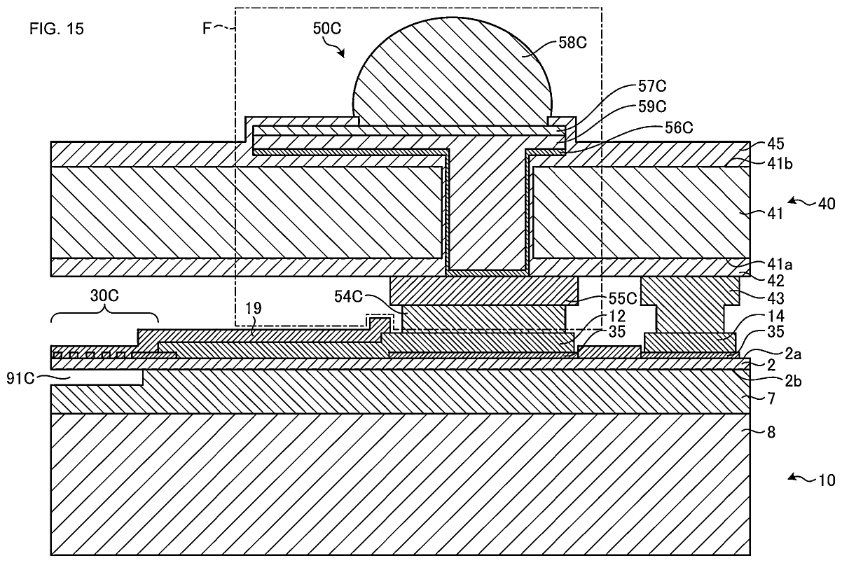

FIG. 13 is a plan view illustrating a portion of the acoustic wave device according to the first example embodiment. FIG. 13 is a view of an acoustic wave element substrate 10 of the acoustic wave device in plan view from the side where a cover 40 is provided. FIG. 14 is a cross-sectional view taken along line XIV-XIV in FIG. 13. FIG. 15 is a cross-sectional view taken along line XV-XV in FIG. 13. As illustrated in FIGS. 13 to 15, the acoustic wave device according to the first example embodiment includes the acoustic wave element substrate 10 and a cover 40. In the following description, one of the directions parallel or substantially parallel to the Z direction may be described as “up”.

As illustrated in FIG. 13, the acoustic wave element substrate 10 includes a plurality of resonators SR1, SR2, and PR1. Here, the resonator SR1 is a resonator including a functional electrode 30A, the resonator SR2 is a resonator including a functional electrode 30B, and the resonator PR1 is a resonator including a functional electrode 30C. An acoustic wave device according to a first example embodiment is, for example, a ladder filter including a serial arm resonator inserted in series into a signal path (hereinafter first path) from an input terminal to an output terminal, and a parallel arm resonator inserted into a path (hereinafter a second path) between a node on the first path and a reference potential. Here, the input terminal is an extraction electrode 50A, the output terminal is an extraction electrode 50B, and the reference potential is connected to an extraction electrode 50C. The serial arm resonators are the resonator SR1 and the resonator SR2, and the parallel arm resonator is the resonator PR1. The resonators SR1 and SR2, which are serial arm resonators, include one terminal that is electrically connected to the extraction electrode 50A which is an input terminal, and the other terminal that is electrically connected to the extraction electrode 50B which is an output terminal. Here, the resonator SR1 and the resonator SR2 are electrically connected in series. The resonator PR1 includes one terminal that is electrically connected to a wiring 12 that connects the resonator SR1 and the resonator SR2 and the other terminal that is electrically connected to an extraction electrode 50C that is coupled to a reference potential.

In the first example embodiment, the acoustic wave element substrate 10 includes the functional electrodes 30A to 30C, a support, the piezoelectric layer 2, a first metal layer 35, the second metal layer 14, and a dielectric film 19.

The support includes the support substrate 8. The support substrate 8 is an example of a “first substrate”. The support substrate 8 is, for example, a silicon substrate. In the first example embodiment, the support further includes the intermediate layer 7. The intermediate layer 7 is laminated on the support substrate 8. The intermediate layer 7 is, for example, a layer made of silicon oxide. The intermediate layer 7 is not necessary.

As illustrated in FIGS. 13 to 15, the support is provided with first space portions 91A to 91C. The first space portion 91 is a space formed by etching the sacrificial layer. The first space portions 91A to 91C are provided at positions that overlap at least a portion of the functional electrodes 30A to 30C, respectively, when viewed in plan view in the Z direction. In the first example embodiment, the first space portions 91A to 91C are provided in the intermediate layer 7.

The first space portions 91A to 91C are a space corresponding to the space portion 9 illustrated in FIG. 2.

The first space portions 91A to 91C may be provided on the support substrate 8.

The piezoelectric layer 2 is laminated on the support. As illustrated in FIG. 14, in the first example embodiment, the piezoelectric layer 2 is provided on the support substrate 8 with the intermediate layer 7 interposed therebetween. The piezoelectric layer 2 includes, for example, lithium niobate or lithium tantalate, and may further include inevitable impurities. When the support does not include the intermediate layer 7, the piezoelectric layer 2 is laminated on the support substrate 8. The piezoelectric layer 2 includes the first main surface 2a and the second main surface 2b. The first main surface 2a is the main surface on a second substrate 41 side among the main surfaces of the piezoelectric layer 2. The second main surface 2b is a main surface opposite to the first main surface 2a, and is a main surface of the piezoelectric layer 2 on the support substrate 8 side.

As illustrated in FIG. 1B, the functional electrodes 30A to 30C are IDT electrodes including the first busbar electrode 5, the second busbar electrode 6 facing the first busbar electrode 5, the electrode finger 3 connected to the first busbar electrode 5, and the electrode finger 4 connected to the second busbar electrode 6. The functional electrodes 30A to 30C are provided on at least one of the first main surface 2a and the second main surface 2b of the piezoelectric layer 2. In the first example embodiment, the functional electrodes 30A to 30C are provided on the first main surface 2a of the piezoelectric layer 2.

The first metal layer 35 and the second metal layer 14 are support portions that support the cover 40 on the acoustic wave element substrate 10. The first metal layer 35 is provided on the piezoelectric layer 2. The second metal layer 14 is laminated on the first metal layer 35. The first metal layer 35 and the second metal layer 14 are metal laminated layers including gold or a gold alloy and another metal (for example, titanium or the like). As illustrated in FIG. 15, the first metal layer 35 and the second metal layer 14 include those formed in a linear pattern to surround the functional electrodes 30A to 30C when viewed in plan view in the Z direction. The second metal layer 14 includes the wiring 12 electrically connected to the functional electrodes 30A to 30C. The wiring 12 electrically connects the extraction electrodes 50A to 50C to the resonators SR1, SR2, and PR1. The wiring 12 is thicker than the functional electrodes 30A to 30C. In the first example embodiment, the first metal layer 35 and the second metal layer 14 are made of the same material, but the present disclosure is not limited thereto, and may be made of different materials.

As illustrated in FIG. 14, in the first example embodiment, the dielectric film 19 is provided on the functional electrodes 30A to 30C and on the main surface (first main surface 2a) of the piezoelectric layer 2 on which the functional electrodes 30A to 30C are provided. The dielectric film 19 is made of, for example, silicon oxide.

The cover 40 includes the second substrate 41. As illustrated in FIGS. 14 and 15, in the first example embodiment, the cover 40 includes a second substrate 41, an insulator 42, a sealing metal layer 43, and an insulator 45. Further, the cover 40 includes extraction electrodes 50A to 50D that penetrate the second substrate 41 and the insulators 42 and 45.

The second substrate 41 is a substrate at a position facing the first main surface 2a of the piezoelectric layer 2. The second substrate 41 is a substrate made of a semiconductor or a conductor, for example, a silicon substrate. The second substrate 41 includes a first main surface 41a which is the main surface on the acoustic wave element substrate 10 side and a second main surface 41b which is a main surface on an opposite side of the first main surface 41a. The second main surface 41b of the second substrate 41 is covered with the insulator 45 made of, for example, silicon oxide, and the first main surface 41a of the second substrate 41 is covered with the insulator 42 made of, for example, silicon oxide. The insulators 42 and 45 may be made of an appropriate insulating material such as, for example, aluminum oxide, aluminum nitride, boron nitride, silicon carbide, magnesium oxide, and silicon (high resistance silicon).

The sealing metal layer 43 is a metal layer that causes the acoustic wave element substrate 10 to be supported by the cover 40. As illustrated in FIGS. 14 and 15, the sealing metal layer 43 is provided on a portion of the insulator 42. As illustrated in FIGS. 14 and 15, the sealing metal layer 43 has a linear pattern to surround the functional electrodes 30A to 30C when viewed in plan view in the Z direction. The sealing metal layer 43 is attached to the second metal layer 14 in a linear pattern. Accordingly, the sealing metal layer 43 can seal the space between the acoustic wave element substrate 10 and the cover 40. As a result, the functional electrodes 30A to 30C can be protected. The sealing metal layer 43 is a metal laminated layer including gold or a gold alloy and another metal (for example, titanium or the like). The sealing metal layer 43 is, for example, the same material as the second metal layer 14.

The extraction electrodes 50A to 50D are electrodes to connect the acoustic wave device to an external device. The extraction electrodes 50A to 50C are provided at a position that overlaps the first metal layer 35 when viewed in plan view in the Z direction. At least one extraction electrode of the extraction electrodes defines and functions as an input terminal, at least one extraction electrode defines and functions as an output terminal, and at least one extraction electrode is connected to a reference potential.

In the first example embodiment, the extraction electrode 50A is an electrode that defines and functions as an input terminal, the extraction electrode 50B is an electrode that defines and functions as an output terminal, and the extraction electrode 50C is connected to a reference potential. The extraction electrode 50D is not electrically connected to the resonator. The number of extraction electrodes is merely an example, and more than this may be included. In the first example embodiment, as illustrated in FIG. 13, the extraction electrodes 50A to 50D are provided one by one near the vertex of a rectangle of the cover 40 when viewed in plan view in the Z direction, but this is merely an example, and the position of the extraction electrode is not particularly limited.

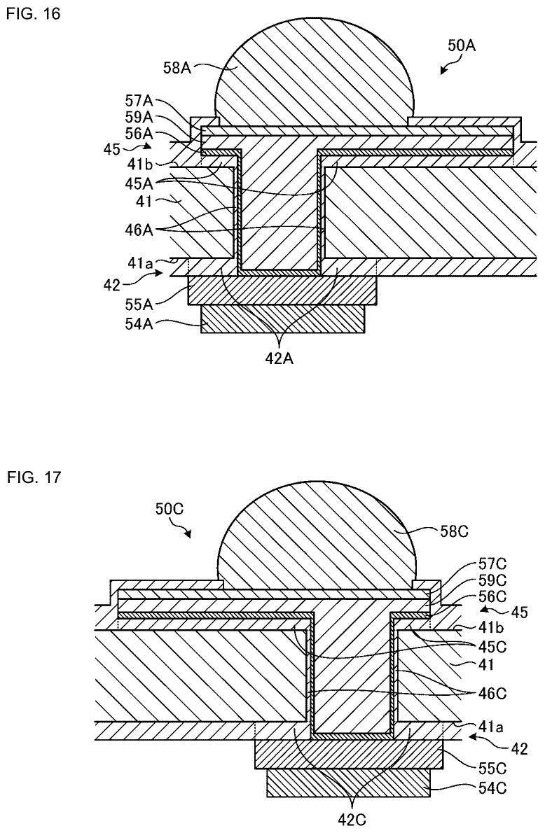

FIG. 16 is an enlarged view of a region E in FIG. 14. FIG. 16 is a cross-sectional view illustrating the extraction electrode 50A. As illustrated in FIG. 16, the extraction electrode 50A penetrates the cover 40. The extraction electrode 50A includes a support portion 54A, a through via 59A, a first land 55A, a second land 57A, a seed layer 56A, and a bump 58A.

The support portion 54A supports the second substrate 41 between the first main surface 2a of the piezoelectric layer 2 and the first main surface 41a of the second substrate 41. In the first example embodiment, the support portion 54A is laminated on the first main surface 2a side of the piezoelectric layer 2 of the first land 55A, which will be described later. As illustrated in FIG. 14, the support portion 54A is provided in a portion surrounded by the sealing metal layer 43. The support portion 54A is attached to the wiring 12 of the second metal layer 14 to bond the cover 40 and the acoustic wave element substrate 10. As a result, bending of the acoustic wave element substrate 10 is reduced or prevented.

The through via 59A penetrates the second substrate 41. The through via 59A is, for example, a bump metal made of Cu.

The first land 55A is provided on the first main surface 41a of the second substrate 41 and electrically connected to the through via 59A. In the first example embodiment, the first land 55A is laminated on the first main surface 41a of the second substrate 41 with the insulator 42 interposed therebetween and on the through via 59A with the seed layer 56A interposed therebetween. As illustrated in FIG. 14, the first land 55A is provided in a portion surrounded by the sealing metal layer 43. The support portion 54A is attached to the support portion 54A to bond the cover 40 and the acoustic wave element substrate 10. As a result, the support portion 54A is electrically connected to the wiring 12.

The second land 57A is provided on the second main surface 41b of the second substrate 41 and electrically connected to the through via 59A. In the first example embodiment, the second land 57A is laminated on the through via 59A on the second main surface 41b side of the second substrate 41. The second land 57A is, for example, a bump metal, and is a multilayer body provided by, for example, plating an Au layer on a Cu layer and a Ni layer.

The seed layer 56A is laminated on the inner surface of the through via 59A and the surface on the second main surface 41b side. The seed layer 56A is, for example, a multilayer body in which a Cu layer is laminated on a Ti layer.

The bump 58A is an electrode laminated on the second land 57A. The bump 58A is, for example, a Ball Grid Array (BGA) bump.

As a result, the bump 58A is electrically connected to the functional electrode 30A.

As illustrated in FIG. 16, an insulator 45A is provided between the second main surface 41b of the second substrate 41 and the second land 57A, an insulator 42A is provided between the first main surface 41a of the second substrate 41 and the first land 55A, and an insulator 46A is provided between the side wall of the through via 59A and the second substrate 41. In other words, the extraction electrode 50A is covered with the insulator entirely between the extraction electrode 50A and the second substrate 41. The insulators 45A, 42A, and 46A are made of, for example, silicon oxide. As a result, the resistance between the extraction electrode 50A and the second substrate 41 increases, and thus generation of leak current from the extraction electrode 50A to the second substrate 41 can be reduced or prevented. Accordingly, the flow of current between the extraction electrodes 50A to 50D can be reduced or prevented.

The extraction electrode 50B penetrates the cover 40. Similar to the extraction electrode 50A, the extraction electrode 50B includes a support portion, a through via, a first land, a second land, a seed layer, and a bump. Similarly to the extraction electrode 50A, in the extraction electrode 50B, an insulator is provided between the first main surface 41a of the second substrate 41 and the first land, an insulator is provided between the second main surface 41b of the second substrate 41 and the second land, and an insulator is provided between the side wall of the through via 59C and the second substrate 41. That is, the extraction electrode 50B is covered with the insulator entirely between the extraction electrode 50B and the second substrate 41. As a result, the resistance between the extraction electrode 50B and the second substrate 41 increases, and thus generation of leak current from the extraction electrode 50B to the second substrate 41 can be reduced or prevented. Accordingly, the flow of current between the extraction electrodes 50A to 50D can be reduced or prevented.

FIG. 17 is an enlarged view of a region F in FIG. 15. FIG. 17 is a cross-sectional view illustrating the extraction electrode 50C. As illustrated in FIG. 17, the extraction electrode 50C penetrates the cover 40. Similar to the extraction electrode 50A, the extraction electrode 50C includes a support portion 54C, a through via 59C, a second land 57C, a first land 55C, a seed layer 56C, and a bump 58C.

As illustrated in FIG. 17, an insulator 45C is provided between the second main surface 41b of the second substrate 41 and the second land 57C, an insulator 42C is provided between the first main surface 41a of the second substrate 41 and the first land 55C, and an insulator 46C is provided between the side wall of the through via 59C and the second substrate 41. That is, the extraction electrode 50C is covered with the insulator entirely between the extraction electrode 50C and the second substrate 41. As a result, the resistance between the extraction electrode 50C and the second substrate 41 increases, and thus the flow of current from the second substrate 41 to the extraction electrode 50A can be reduced or prevented. Accordingly, the flow of current between the extraction electrodes 50A to 50D can be reduced or prevented.

The extraction electrode 50D penetrates the cover 40. In the first example embodiment, similar to the extraction electrode 50A, the extraction electrode 50D includes a support portion, a through via, a first land, a second land, a seed layer, and a bump. Similarly to the extraction electrode 50A, in the extraction electrode 50D, an insulator is provided between the first main surface 41a of the second substrate 41 and the first land, an insulator is provided between the second main surface 41b of the second substrate 41 and the second land, and an insulator is provided between the side wall of the through via 59C and the second substrate 41. That is, the extraction electrode 50D is covered with the insulator entirely between the extraction electrode 50D and the second substrate 41. As a result, the resistance between the extraction electrode 50D and the second substrate 41 increases, and thus the flow of current from the second substrate 41 to the extraction electrode 50D can be reduced or prevented. Accordingly, the flow of current between the extraction electrodes 50A to 50D can be reduced or prevented.

As described above, in the example according to FIG. 13, in all of the extraction electrodes, insulators are provided between the first main surface 41a of the second substrate 41 and the first land, between the second main surface 41b of the second substrate 41 and the second land, and between the side wall of the through via and the second substrate 41. In this case, since all of the extraction electrodes 50A to 50D and the second substrate 41 are insulated, the flow of current between the extraction electrodes can be further reduced or prevented.

Although the example of the acoustic wave device according to the first example embodiment has been described above, the acoustic wave device according to the first example embodiment is not limited thereto. For example, in the example illustrated in FIG. 13, the acoustic wave device includes three resonators SR1, SR2, and PR1, but the present disclosure is not limited thereto, and may include four or more resonators.

As described above, the acoustic wave device according to the first example embodiment includes the first substrate (support substrate 8), the piezoelectric layer 2 that overlaps the first substrate in plan view and includes the first main surface 2a and the second main surface 2b on an opposite side, the functional electrode provided on at least one of the first main surface 2a of the piezoelectric layer 2 and the second main surface 2b of the piezoelectric layer 2, the second substrate 41 that includes the first main surface 41a facing the first main surface 2a of the piezoelectric layer 2 in the first direction and the second main surface 41b on an opposite side, and the plurality of extraction electrodes 50A to 50D including the support portion that supports the second substrate 41 between the first main surface 2a of the piezoelectric layer 2 and the first main surface 41a of the second substrate 41, the through via that penetrates the second substrate 41, the first land that is provided on the first main surface 41a of the second substrate 41 and is electrically connected to the through via, and the second land that is provided on the second main surface 41b of the second substrate 41 and is electrically connected to the through via, in which, in at least one of the extraction electrodes 50A, the insulators 42A, 45A, and 46A are provided between the first main surface 41a of the second substrate 41 and the first land 55A, between the second main surface 41b of the second substrate 41 and the second land 57A, and between the side wall of the through via 59A and the second substrate 41. As a result, the resistance between the extraction electrode 50A and the second substrate 41 increases, and thus the flow of current between the extraction electrodes can be reduced or prevented.

Further, the second substrate 41 may be, for example, a silicon substrate. Even in this case, the resistance between the extraction electrode 50A and the second substrate 41 increases, and thus the flow of current between the extraction electrodes can be reduced or prevented.

In all of the extraction electrodes 50A to 50D, insulators pay be provided between the first main surface of the second substrate 41 and the first land, between the second main surface of the second substrate 41 and the second land, and between the side wall of the through via and the second substrate 41. Accordingly, since all the extraction electrodes 50A to 50D and the second substrate 41 are insulated, the flow of current between the extraction electrodes can be further reduced or prevented.

The functional electrodes 30A to 30C may include one or more first electrode fingers 3 extending in the second direction that intersects with the first direction, and one or more second electrode fingers 4 facing any one of the one or more first electrode fingers 3 in the third direction orthogonal or substantially orthogonal to the second direction and extending in the second direction. Accordingly, an acoustic wave device in which good resonance characteristics are obtained can be provided.

The thickness of the piezoelectric layer 2 is, for example, 2p or less when p is a center-to-center distance between the first electrode finger 3 and the second electrode finger 4 adjacent to each other, in the one or more first electrode fingers 3 and the one or more second electrode fingers 4. Accordingly, the acoustic wave device 1 can be reduced in size, and the Q value can be increased.

The piezoelectric layer 2 may include, for example, lithium niobate or lithium tantalate. Accordingly, an acoustic wave device in which good resonance characteristics are obtained can be provided.

A bulk wave in a thickness slip mode can be used. Accordingly, an acoustic wave device in which the coupling coefficient increases and good resonance characteristics are obtained can be provided.

d/p≤about 0.5 where d is a thickness of the piezoelectric layer 2, and p is a center-to-center distance between the first electrode finger 3 and the second electrode finger 4 adjacent to each other, in the one or more first electrode fingers 3 and the one or more second electrode fingers 4. Accordingly, the acoustic wave device 1 can be reduced in size, and the Q value can be increased.

d/p may be, for example, about 0.24 or less. Accordingly, the acoustic wave device 1 can be reduced in size, and the Q value can be increased.

MR≤about 1.75 (d/p)+0.075 where the excitation region C is a region in which the first electrode fingers 3 and the second electrode fingers 4 adjacent to each other overlap each other when viewed in the facing direction, and MR is a metallization ratio of the one or more first electrode fingers 3 and the one or more second electrode fingers 4 to the excitation region C. In this case, the fractional band can be reliably set to about 17% or less.

A plate wave can be used. Accordingly, an acoustic wave device in which good resonance characteristics are obtained can be provided.

The piezoelectric layer 2 may be, for example, lithium niobate or lithium tantalate, and Euler angles (qp, θ, ψ) of the lithium niobate or the lithium tantalate are in a range of the following Formula (1), Formula (2), and Formula (3). In this case, the fractional band can be sufficiently widened.

(0°±10°,0° to 20°,any ψ) Formula (1)

(0°±10°,20° to 80°,0° to 60°(1−(θ−50)²/900)^{1/2})or(0°±10°,20° to 80°,[180°−60°(1−(θ−50)²/900)^{1/2}] to 180°) Formula (2)

(0°±10°,[180°−30°(1−(ψ−90)²/8100)^{1/2}] to 180°,any ψ) Formula (3)

A method of manufacturing an acoustic wave device according to a first example embodiment of the present invention includes a first substrate lamination process, a second substrate lamination process, a bonding process, a second substrate thinning process, a first insulator forming process, a through-hole forming process, a second insulator forming process, an insulator removal process, a seed layer forming process, a through electrode forming process, a seed layer removal process, a third insulator forming process, and a bump forming process. Hereinafter, an example of the method of manufacturing the acoustic wave device according to the first example embodiment will be described with reference to a cross-sectional view taken along line XIV-XIV in FIG. 13, that is, a cross-sectional view according to the extraction electrode 50A as an example.

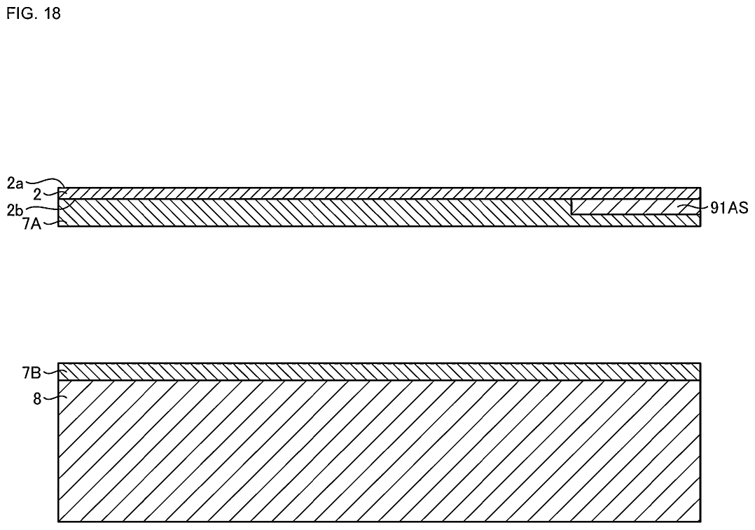

FIGS. 18 to 20 are cross-sectional views for explaining the first substrate lamination process according to the first example embodiment. The first substrate lamination process is a process of laminating the piezoelectric layer 2 and the functional electrodes 30A to 30C on the support substrate 8 in the first direction. In the first substrate lamination process according to the first example embodiment, by bonding the support and the piezoelectric layer 2, forming an electrode such as the functional electrode 30A, and forming the first space portions 91A to 91C, the acoustic wave element substrate 10 according to the first example embodiment is formed.

First, as illustrated in FIG. 18, a sacrificial layer 91AS is formed on the second main surface of the piezoelectric layer 2, and then a first portion 7A, which is the intermediate layer 7, is formed to cover the second main surface of the piezoelectric layer 2 and the sacrificial layer 91AS. The first portion 7A includes a flattened surface such that unevenness due to the influence of the sacrificial layer 91AS is reduced or prevented. Next, a second portion 7B that becomes the intermediate layer 7 is formed on the support substrate 8. Then, the first portion 7A and the second portion 7B are bonded to each other, and the piezoelectric layer 2 (piezoelectric substrate) is supported by the support substrate 8.

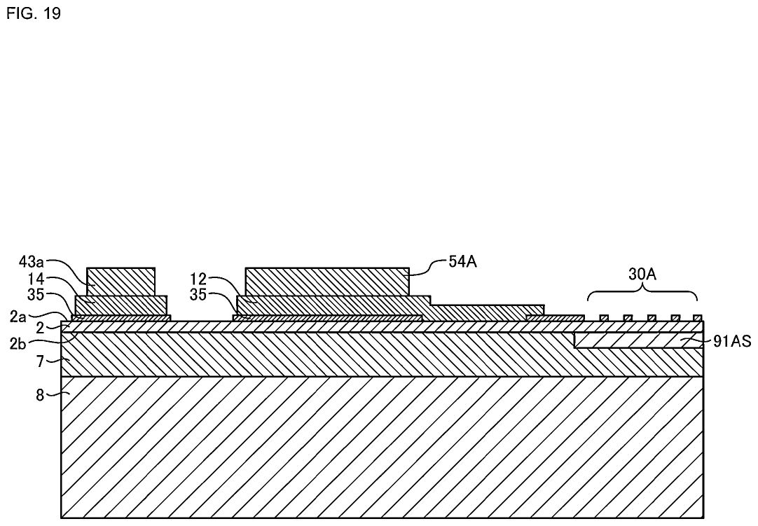

Next, as illustrated in FIG. 19, electrodes are formed on the piezoelectric layer 2. Specifically, the first metal layer 35 is formed on the first main surface of the piezoelectric layer 2, and the functional electrode 30A is patterned. Then, the second metal layer 14 is formed on the first metal layer 35. Here, a portion of the second metal layer 14 becomes the wiring 12 that is electrically conducted to the functional electrode 30A. After that, a sealing metal layer 43a and a support portion 54A are laminated on the second metal layer 14. Here, the sealing metal layer 43a is a layer of, for example, Au or an Au alloy. After the electrode formation, the periphery of the functional electrode 30A is masked with a resist, and the dielectric film 19 is formed. As a result, the functional electrode 30A is covered with the dielectric film 19.

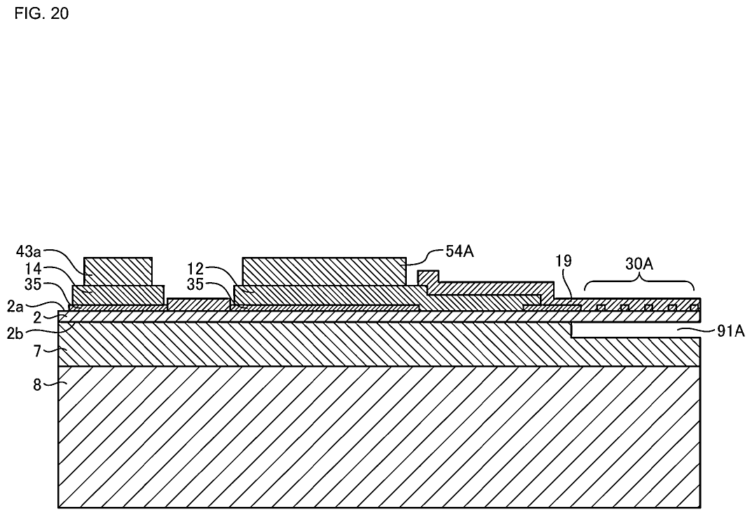

Then, as illustrated in FIG. 20, the first space portion 91A is formed in the piezoelectric layer 2.

Specifically, an etchant is injected into a through-hole (not illustrated) provided in the piezoelectric layer to dissolve the sacrificial layer 91AS. As a result, the space in which the sacrificial layer 91AS is located becomes the first space portion 91. After that, a measuring instrument is connected to the wiring 12, and after the frequency characteristics are confirmed, the film thickness of the dielectric film 19 is adjusted by, for example, ion etching or the like. The adjustment of the film thickness of the dielectric film 19 is repeated until desired frequency characteristics are obtained.

By the first substrate lamination process described above, the acoustic wave element substrate 10 can be manufactured. The method of manufacturing the acoustic wave element substrate 10 described above is merely an example, and the method of manufacturing the acoustic wave element substrate 10 is not limited thereto.

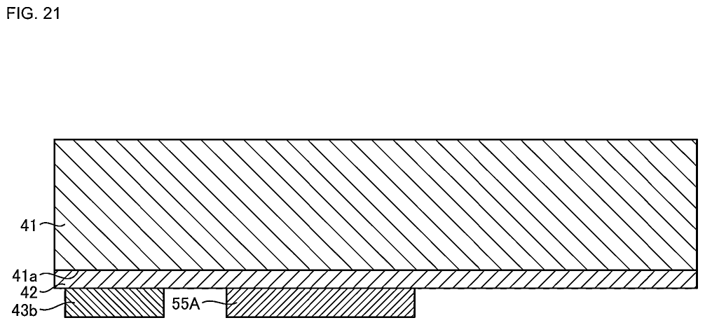

FIG. 21 is a cross-sectional view for explaining a second substrate lamination process according to the first example embodiment. As illustrated in FIG. 21, the second substrate lamination process is a process of laminating an insulator 42, a first land 55A, and a sealing metal layer 43b on the first main surface 41a of the second substrate 41. Here, the first land 55A and the sealing metal layer 43b are laminated on the first main surface 41a of the second substrate 41 with the insulator 42 interposed therebetween.

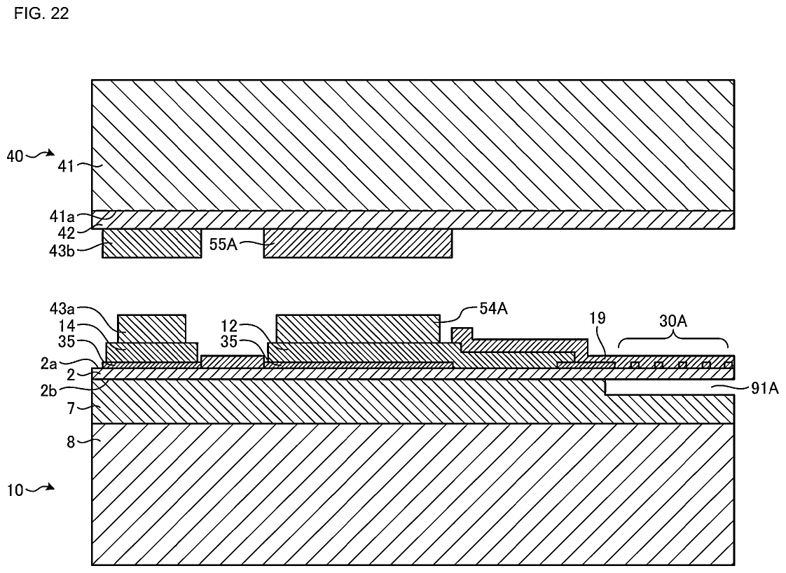

FIG. 22 is a cross-sectional view for explaining a bonding process according to the first example embodiment.

As illustrated in FIG. 22, the bonding process is a process of bonding the acoustic wave element substrate 10 and the cover 40 to each other such that the first main surface 2a of the piezoelectric layer 2 and the first main surface 41a of the second substrate 41 face each other. Specifically, the sealing metal layer 43a of the acoustic wave element substrate 10 and the sealing metal layer 43b of the cover 40 are Au—Au bonded, and the sealing metal layer 43a and the sealing metal layer 43b are integrated to be the sealing metal layer 43. Further, the support portion 54A of the acoustic wave element substrate 10 and the first land 55A of the cover 40 are Au—Au bonded.

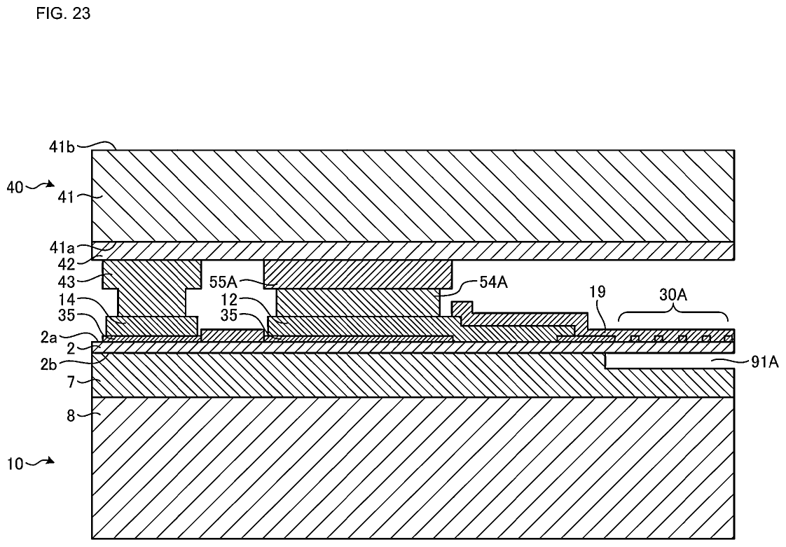

FIG. 23 is a cross-sectional view for explaining a second substrate thinning process according to the first example embodiment. As illustrated in FIG. 23, the second substrate thinning process is a process of grinding the second substrate 41 and reducing the thickness of the second substrate 41. As a result, the second main surface 41b of the second substrate 41 is formed.

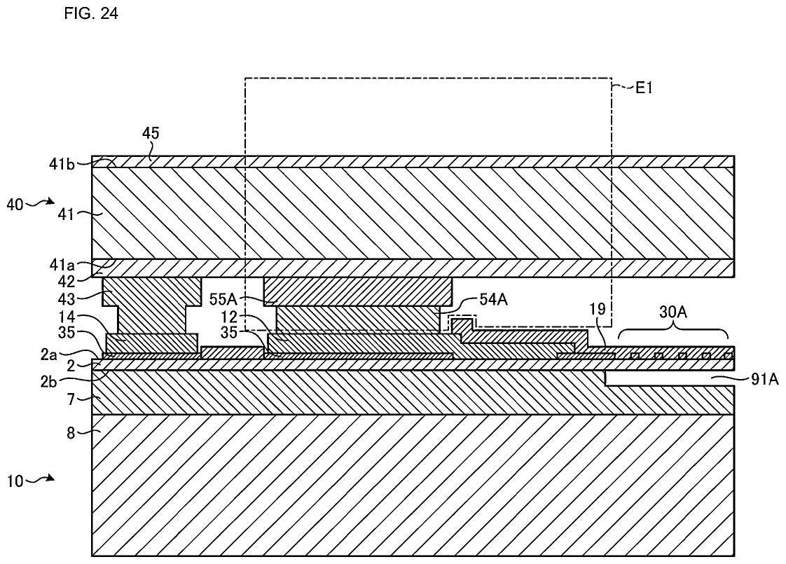

FIG. 24 is a cross-sectional view for explaining the first insulator forming process according to the first example embodiment. As illustrated in FIG. 24, the first insulator forming process is a process of forming the insulator 45 on the second main surface 41b of the second substrate 41. In the first example embodiment, the insulator 45 is formed on the entire or substantially the entire surface of the second main surface 41b of the second substrate 41.

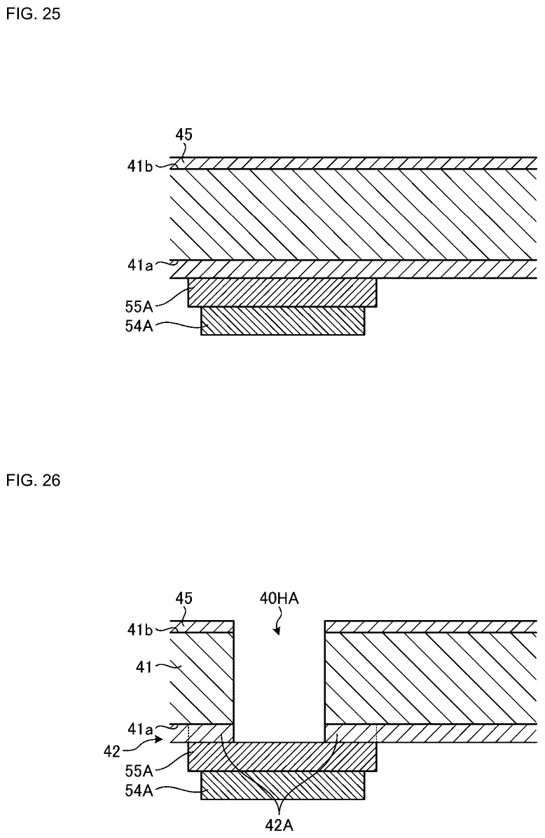

FIG. 25 is an enlarged view of a region E1 in FIG. 24. That is, FIG. 25 is an enlarged cross-sectional view of the cover 40 at a portion where the extraction electrode 50A is provided. Hereinafter, the method of manufacturing the extraction electrode 50A of the acoustic wave device according to the first example embodiment will be described with reference to an enlarged view related to the region E1.

FIG. 26 is a cross-sectional view for explaining the through-hole forming process according to the first example embodiment. As illustrated in FIG. 26, the through-hole forming process is a process of forming a through-hole 40HA in the second substrate 41. In the first example embodiment, the through-hole 40HA is formed by, for example, dry etching, reactive ion etching, or the like to penetrate the second substrate 41 and the insulators 42 and 45. The through-hole 40HA is provided at a position that overlaps the first land 55A in plan view. As a result, the main surface of the first land 55A on the second substrate 41 side is exposed.

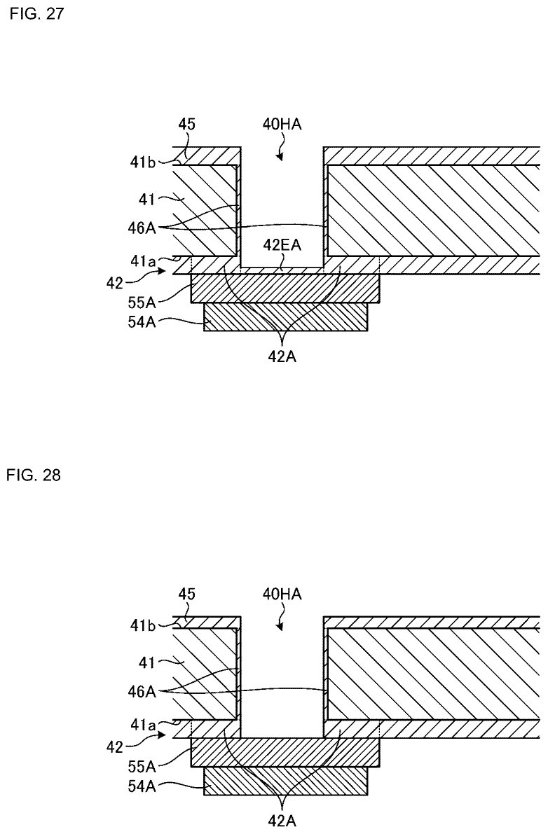

FIG. 27 is a cross-sectional view for explaining the second insulator forming process according to the first example embodiment. As illustrated in FIG. 27, the second insulator forming process is a process of forming the insulators 45, 46A, and 42EA on the second main surface 41b of the second substrate 41, the side wall of the through-hole 40HA, and the surface of the first land 55A exposed to the through-hole 40HA. In the first example embodiment, in the second insulator forming process, the insulator 45 on the second main surface 41b of the second substrate 41 is additionally formed by, for example, the chemical vapor deposition method or the like, the insulator 46A is formed on the side wall of the through-hole 40HA, and the insulator 42EA is formed on the surface of the first land 55A exposed to the through-hole 40HA.

FIG. 28 is a cross-sectional view for explaining the insulator removal process according to the first example embodiment. As illustrated in FIG. 28, the insulator removal process is a process of removing a portion of the insulator formed in the second insulator forming process. In the first example embodiment, the thinning of the insulator 45 on the second main surface 41b and the removal of the insulator 42EA formed on the surface of the first land 55A exposed to the through-hole 40HA are performed by, for example, etchback or the like. As a result, the surface of the first land 55A exposed to the through-hole 40HA is exposed.

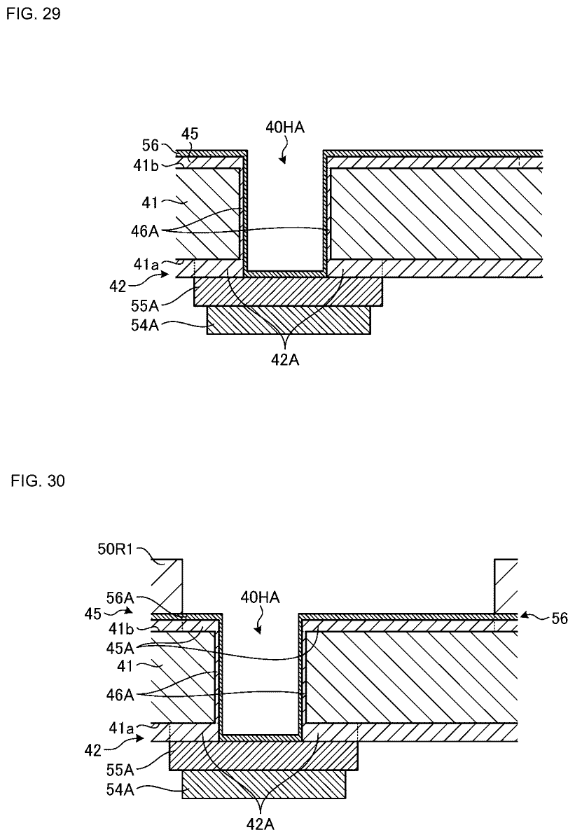

FIG. 29 is a schematic cross-sectional view for explaining the seed layer forming process according to the first example embodiment. As illustrated in FIG. 29, the seed layer forming process is a process of forming a seed layer 56 on the second main surface 41b of the second substrate 41, the side wall of the through-hole 40HA, and the surface of the first land 55A exposed to the through-hole 40HA. In the first example embodiment, for example, the seed layer 56A is formed by forming a Ti layer by sputtering or the like and thereafter laminating a Cu layer on the Ti layer.

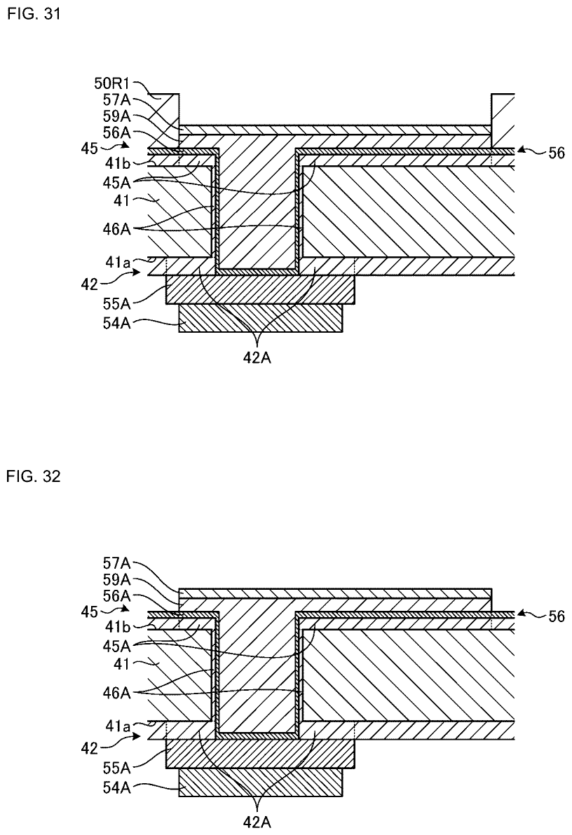

FIGS. 30 to 32 are cross-sectional views for explaining the through electrode forming process according to the first example embodiment. As illustrated in FIGS. 30 and 31, the through electrode forming process is a process of forming the through via 59A and the second land 57A in the through-hole 40HA and a part of the second main surface 41b of the second substrate 41. In the first example embodiment, first, as illustrated in FIG. 30, patterning is performed with a plating resist 50R1 on the seed layer 56A. Next, as illustrated in FIG. 31, for example, the through via 59A is formed by burying the through-hole 40HA with Cu on the seed layer 56, and a Cu layer, a Ni layer, and an Au layer are laminated in this order by plating to form second land 57A. Then, as illustrated in FIG. 32, the plating resist 50R1 is removed. As a result, the second land 57A is laminated on the second main surface 41b of the second substrate 41 with the insulator 45A interposed therebetween.

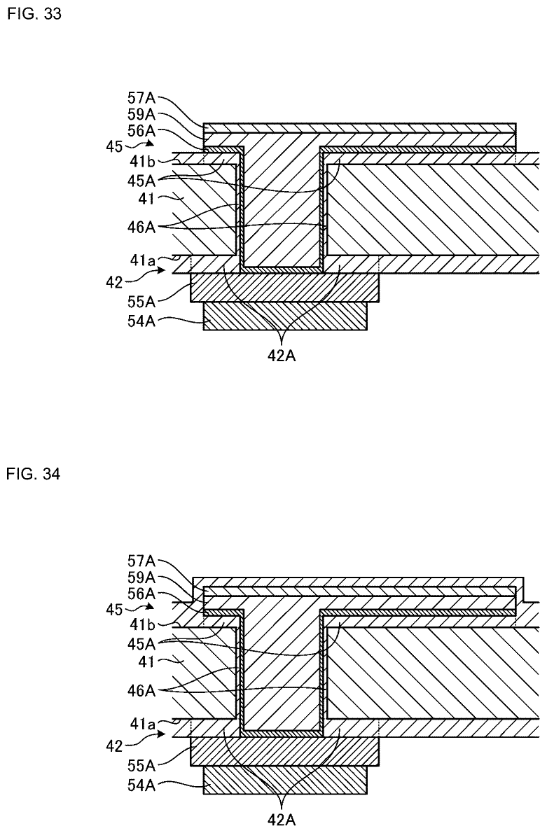

FIG. 33 is a cross-sectional view for explaining the seed layer removal process according to the first example embodiment. As illustrated in FIG. 33, the seed layer removal process is a process of removing the seed layer 56 excluding the seed layer 56A at a portion that overlaps the second land 57A in plan view. The seed layer 56 is removed by, for example, cutting.

FIG. 34 is a cross-sectional view for explaining the third insulator forming process according to the first example embodiment. As illustrated in FIG. 34, the third insulator forming process is a process of forming the insulator 45 on the second main surface 41b of the second substrate 41 and the second land 57A. In the first example embodiment, in the second insulator forming process, the insulator 45 on the second main surface 41b of the second substrate 41 is additionally formed by the chemical vapor deposition method or the like, and the insulator 45 is formed on the second land 57A.

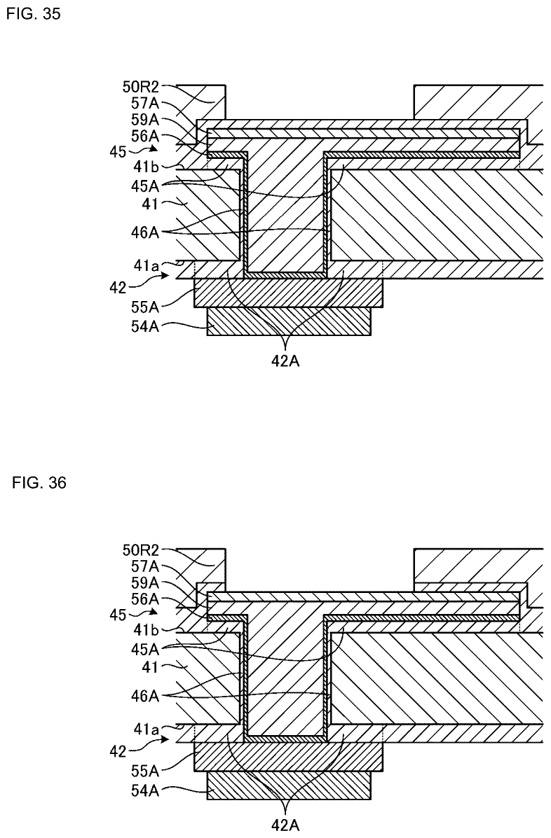

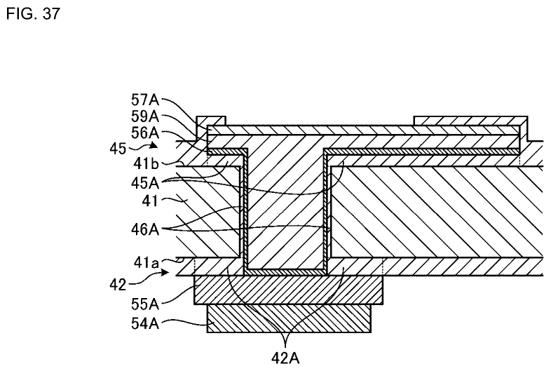

FIGS. 35 to 37 are cross-sectional views for explaining the bump forming process according to the first example embodiment. As illustrated in FIGS. 35 to 37, the bump forming process is a process of removing a portion of the insulator formed on the second land 57A in the second insulator forming process to form the bump 58A. In the first example embodiment, as illustrated in FIG. 35, first, patterning is performed with a resist 50R2 on the second main surface 41b of the second substrate 41 and a portion of the second land 57A. Next, as illustrated in FIG. 36, a portion of the insulator 45 is removed by etching. Then, as illustrated in FIG. 37, the resist 50R2 is removed. As a result, a portion of the second land 57A is exposed. After that, the bump 58A is formed on the surface exposed by the second land 57A.

With the above processes, the extraction electrode 50A can be manufactured. In the first example embodiment, the other extraction electrodes 50B to 50D are manufactured by the same or similar method.

With the above processes, the acoustic wave device according to the first example embodiment can be manufactured. In the acoustic wave device, since the entire or substantially the entire space between the extraction electrodes 50A to 50D and the second substrate 41 is covered with the insulating layer, the resistance between the extraction electrode 50A and the second substrate 41 increases, and thus the flow of current between the extraction electrodes can be reduced or prevented. The method of manufacturing the acoustic wave device according to the first example embodiment described above is merely an example, and the present disclosure is not limited thereto. For example, the third insulator forming process may not be performed, and the bump 58A may be formed on the second land 57A after the seed removal process.

As described above, the method of manufacturing an acoustic wave device according to the first example embodiment includes the first substrate lamination process of laminating the piezoelectric layer 2 including the first main surface 2a and the second main surface 2b on an opposite side of the first main surface 2a, and the functional electrodes 30A to 30C provided on at least one of the first main surface 2a and the second main surface 2b of the piezoelectric layer 2, in the first direction on the first substrate (support substrate 8), the second substrate lamination process of laminating the insulator 42 and the first land 55A on the first main surface 41a of the second substrate 41 including the first main surface 41a and the second main surface 41b on an opposite side of the first main surface 41a, the bonding process of bonding the first substrate and the second substrate 41 such that the first main surface 2a of the piezoelectric layer 2 and the first main surface 41a of the second substrate 41 face each other, the first insulator forming process of forming the insulator 45 on at least a portion of the second main surface 41b of the second substrate 41, the through-hole forming process of forming the through-hole 40HA that penetrates the second substrate 41 at a position that overlaps the first land 55A in plan view, the second insulator forming process of forming the insulators 42EA, 45A, and 46A on the second main surface 41b of the second substrate 41, the side wall of the through-hole 40HA, and the surface of the first land 55A exposed to the through-hole 40HA, the insulator removal process of removing a portion (insulator 42EA) of the insulator formed in the second insulator forming process, and the through electrode forming process of forming the through via 59A and the second land 57A in the through-hole 40HA and the second main surface 41b of the second substrate 41 after the insulator removal process, in the second substrate lamination process, the first land 55A is laminated on the first main surface 41a of the second substrate 41 with the insulator 42 interposed therebetween, in the insulator removal process, at least a portion of the surface of the first land 55A on the second substrate 41 side at a position that overlaps the through-hole 40HA is exposed in plan view, and in the through electrode forming process, at least one second land 57A is formed on the second main surface 41b of the second substrate 41 with the insulator 45A interposed therebetween. As a result, the resistance between the extraction electrode 50A and the second substrate 41 increases, and thus the flow of current between the extraction electrodes can be reduced or prevented.

### Second Example Embodiment

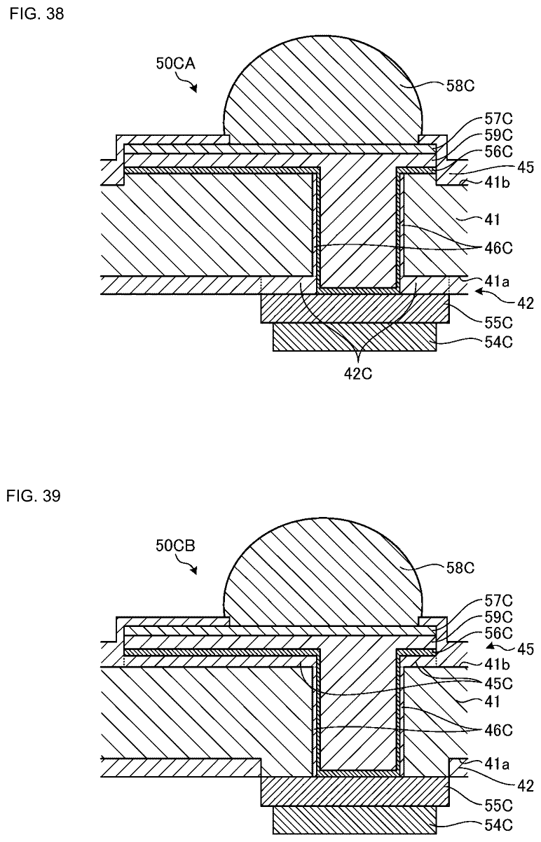

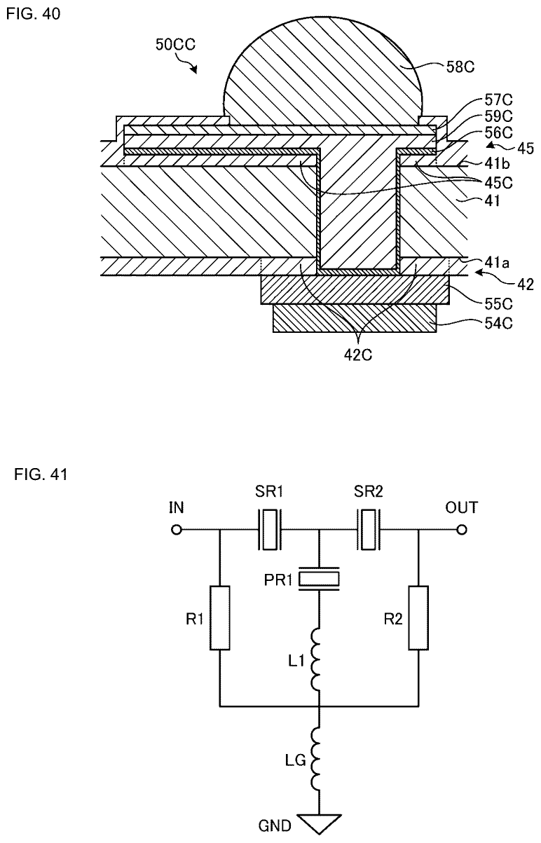

FIG. 38 is a cross-sectional view illustrating an extraction electrode connected to a reference potential according to a first example of an acoustic wave device according to a second example embodiment of the present invention. FIG. 39 is a cross-sectional view illustrating an extraction electrode connected to a reference potential according to a second example of the acoustic wave device according to the second example embodiment. FIG. 40 is a cross-sectional view illustrating an extraction electrode connected to a reference potential according to a third example of the acoustic wave device according to the second example embodiment. FIGS. 38 to 40 are cross-sectional views corresponding to FIG. 17 of the acoustic wave device according to the second example embodiment.

As illustrated in FIGS. 38 to 40, the acoustic wave device according to the second example embodiment is different from the first example embodiment in that the entire or substantially the entire space between the extraction electrodes 50CA to 50CC connected to the reference potential and the second substrate 41 is not covered with an insulator. Hereinafter, the acoustic wave device according to the second example embodiment will be described with reference to the drawings. The portions in common with the acoustic wave device according to the first example embodiment will be denoted by the same reference numerals, and the description thereof will be omitted.

In the second example embodiment, in the extraction electrodes 50CA to 50CC connected to the reference potential, as illustrated in FIGS. 38 to 40, the insulator is not provided at least at one location among the locations between the first main surface 41a of the second substrate 41 and the first land 55C, between the second main surface 41b of the second substrate 41 and the second land 57C, and between the side wall of the through via 59C and the second substrate 41. Accordingly, the parasitic inductance of the extraction electrode connected to the reference potential can be reduced.

In the extraction electrode 50CA connected to the reference potential according to the first example, as illustrated in FIG. 38, the insulator 42C is provided between the first main surface 41a of the second substrate 41 and the first land 55C, the insulator 46C is provided between the side wall of the through via 59C and the second substrate 41, but there is no insulator between the second main surface 41b of the second substrate 41 and the second land 57C.

In the extraction electrode 50CB connected to the reference potential according to the second example, as illustrated in FIG. 39, the insulator 45C is provided between the second main surface 41b of the second substrate 41 and the second land 57C, the insulator 46C is provided between the side wall of the through via 59C and the second substrate 41, but there is no insulator between the first main surface 41a of the second substrate 41 and the first land 55C.

In the extraction electrode 50CC connected to the reference potential according to the third example, as illustrated in FIG. 40, the insulator 45C is provided between the second main surface 41b of the second substrate 41 and the second land 57C, the insulator 42C is provided between the first main surface 41a of the second substrate 41 and the first land 55C, but there is no insulator between the side wall of the through via 59C and the second substrate 41.

The presence or absence of an insulator between the extraction electrode connected to the reference potential and the second substrate 41 is not limited to that illustrated in FIGS. 38 to 40. That is, there may be no insulator at all between the extraction electrode connected to the reference potential and the second substrate 41. Further, there is a possibility that a portion of the insulator is not provided at least at one location among the locations between the second main surface 41b of the second substrate 41 and the second land 57C, between the first main surface 41a of the second substrate 41 and the first land 55C, and between the side wall of the through via 59C and the second substrate 41.

In the second example embodiment, the second substrate 41 has an electric resistivity of, for example, about 100 Ω·cm or less. The second substrate 41 is preferably, for example, a silicon substrate. As a result, the electric resistivity can be set to, for example, about 1 Ω·cm or less. Accordingly, when a plurality of extraction electrodes connected to the reference potential are provided, the resistance between the extraction electrodes connected to the plurality of reference potentials can be reduced.

FIG. 41 is a circuit diagram illustrating one example of the acoustic wave device according to the second example embodiment. FIG. 41 is a circuit diagram of the acoustic wave device illustrated in FIGS. 38 to 40. As illustrated in FIG. 41, similarly to the first example embodiment, the acoustic wave device according to the second example embodiment is, for example, a ladder filter including the serial arm resonator inserted into a first path in series and a parallel arm resonator inserted into a second path. Here, an input terminal IN is an extraction electrode 50A, an output terminal OUT is an extraction electrode 50B, and a reference potential GND is connected to the extraction electrode 50C. The resistance R1 is a resistance between the extraction electrode 50A which is the input terminal IN and the second substrate 41. The resistance R2 is a resistance between the extraction electrode 50B which is the output terminal OUT and the second substrate 41. An inductance L1 is a parasitic inductance of the extraction electrode 50C connected to the reference potential GND. The inductance LG is a parasitic inductance between the second substrate 41 and the reference potential GND.

In the acoustic wave device according to the second example embodiment, since the entire or substantially the entire space between the second substrate 41 and the extraction electrode 50A which is the input terminal IN and the extraction electrode 50B which is the output terminal OUT is covered with the insulator, and the resistance R1 and the resistance R2 can increase. Accordingly, the flow of current between the extraction electrodes 50A and 50B can be reduced or prevented.

In the acoustic wave device according to the second example embodiment, the extraction electrodes 50CA to 50CC connected to the reference potential include portions that are not covered with the insulator between the second substrate 41 and the extraction electrodes 50CA to 50CC. Therefore, the extraction electrode connected to the reference potential is electrically conducted to the second substrate 41. Accordingly, since the inductance L1 of the extraction electrodes 50CA to 50CC connected to the reference potential can be reduced, the attenuation pole can be changed and the out-of-band attenuation can be reduced. When a plurality of extraction electrodes connected to the reference potential are provided, since the plurality of extraction electrodes connected to the reference potential are electrically conducted to the second substrate 41, the inductance of the plurality of extraction electrodes connected to the reference potential can be reduced, and thus the out-of-band attenuation can be reduced.

As described above, in the acoustic wave device according to the second example embodiment, the extraction electrode 50CA that is connected to the reference potential includes no insulator at least at a portion between the first main surface 41a of the second substrate 41 and the first land 55C. Accordingly, the inductance L1 of the extraction electrode 50CA connected to the reference potential can be reduced, and thus the out-of-band attenuation can be reduced.

In addition, in the acoustic wave device according to the second example embodiment, the extraction electrode 50CB that is connected to the reference potential includes no insulator at least at a portion between the second main surface 41b of the second substrate 41 and the second land 57C. Accordingly, the inductance L1 of the extraction electrode 50CB connected to the reference potential can be reduced, such that the out-of-band attenuation can be reduced.

In addition, in the acoustic wave device according to the second example embodiment, the extraction electrode 50CC that is connected to the reference potential includes no insulator at least at a portion between the side wall of the through via 59C and the second substrate 41. Accordingly, the inductance L1 of the extraction electrode 50CC connected to the reference potential can be reduced, and thus the out-of-band attenuation can be reduced.

An example of a method of manufacturing an acoustic wave device according to the second example embodiment is different from the first example embodiment in that, in the through electrode forming process, the second land 57C related to the extraction electrode 50CA connected to the reference potential is formed on the second main surface 41b of the second substrate 41 without an insulator interposed therebetween. Here, the portions related to the extraction electrodes 50A and 50B are manufactured by the same or substantially the same method as that of the first example embodiment. Hereinafter, with reference to drawings, an example of the method of manufacturing the acoustic wave device according to the second example embodiment will be described with reference to a cross-sectional view related to the extraction electrode 50CA connected to a reference potential as an example. The description of the processes in common with the method of manufacturing the acoustic wave device according to the first example embodiment will be omitted.

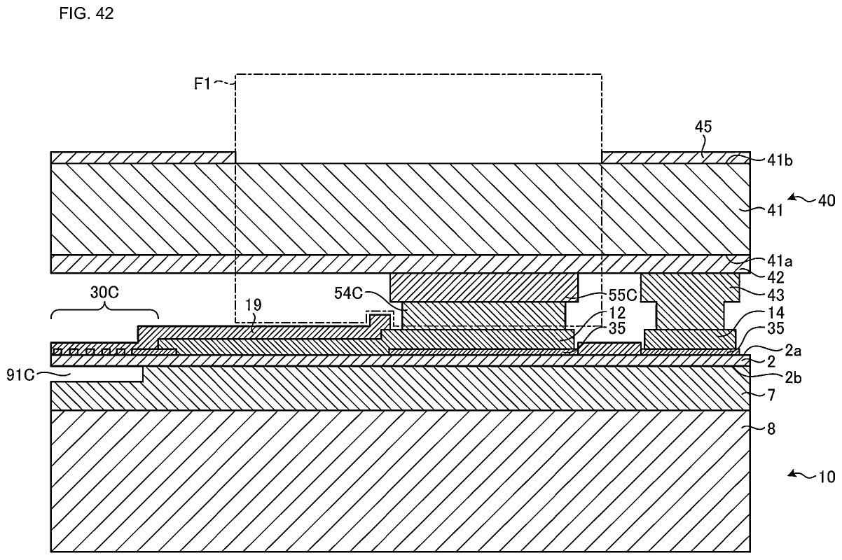

FIG. 42 is a cross-sectional view for explaining the first insulator forming process according to the second example embodiment. As illustrated in FIG. 42, in the second example embodiment, the insulator 45 is formed on a portion of the second main surface 41b of the second substrate 41 in the first insulator forming process. More specifically, after the insulator 45 is formed on the entire or substantially the entire surface of the second main surface 41b of the second substrate 41, and a portion of the insulator 45 of the second main surface 41b of the second substrate 41 is removed by etching or the like to expose the second main surface 41b. Here, the portion that exposes the second main surface 41b of the second substrate 41 is the portion of the second main surface 41b of the second substrate 41 where the second land 57C of the extraction electrode 50CA connected to the reference potential is provided.

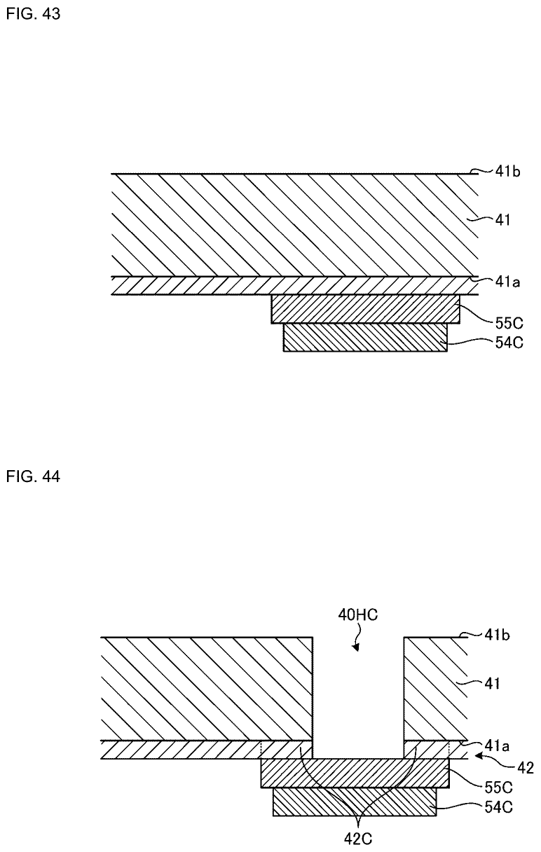

FIG. 43 is an enlarged view of a region F1 in FIG. 42. That is, FIG. 42 is an enlarged cross-sectional view of the cover 40 at a portion where the extraction electrode 50CA connected to the reference potential is provided. Hereinafter, the method of manufacturing the extraction electrode 50CA of the acoustic wave device according to the second example embodiment will be described with reference to an enlarged view related to the region F1.

FIG. 44 is a cross-sectional view for explaining the through-hole forming process according to the second example embodiment. As illustrated in FIG. 44, in the through-hole forming process, similarly to the first example embodiment, a through-hole 40HC is formed to penetrate the second substrate 41 and the insulators 42 and 45. The through-hole 40HC is provided at a position that overlaps the first land 55C in plan view. As a result, the main surface of the first land 55C on the second substrate 41 side is exposed.

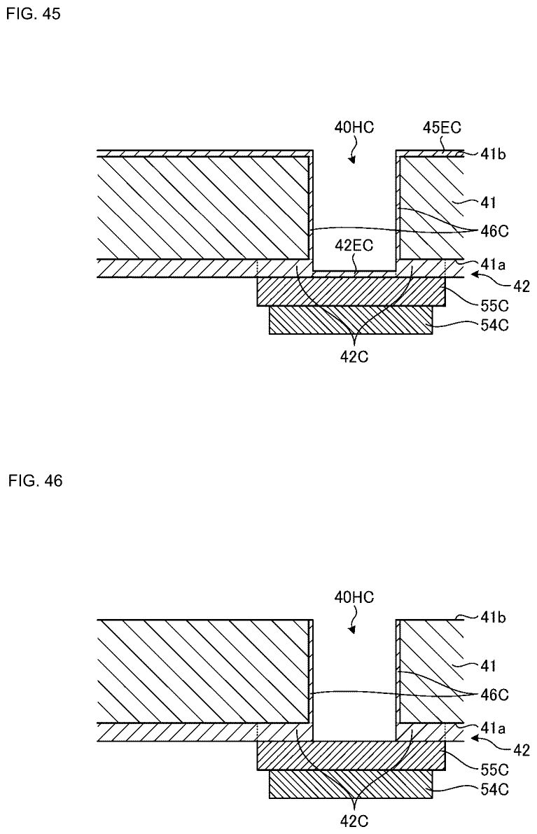

FIG. 45 is a cross-sectional view for explaining the second insulator forming process according to the second example embodiment. As illustrated in FIG. 45, in the second example embodiment, the insulator 45EC on the second main surface 41b of the second substrate 41 is formed by, for example, the chemical vapor deposition method or the like, the insulator 46C is formed on the side wall of the through-hole 40HC, and the insulator 42EC is formed on the surface of the first land 55C exposed to the through-hole 40HC.

FIG. 46 is a cross-sectional view for explaining the insulator removal process according to the second example embodiment. As illustrated in FIG. 46, in the second example embodiment, the removal of the insulator 45EC on the second main surface 41b and the removal of the insulator 42EC formed on the surface of the first land 55C exposed to the through-hole 40HC are performed by, for example, etchback or the like. As a result, the second main surface 41b of the second substrate 41 and the surface of the first land 55C exposed to the through-hole 40HC are exposed.

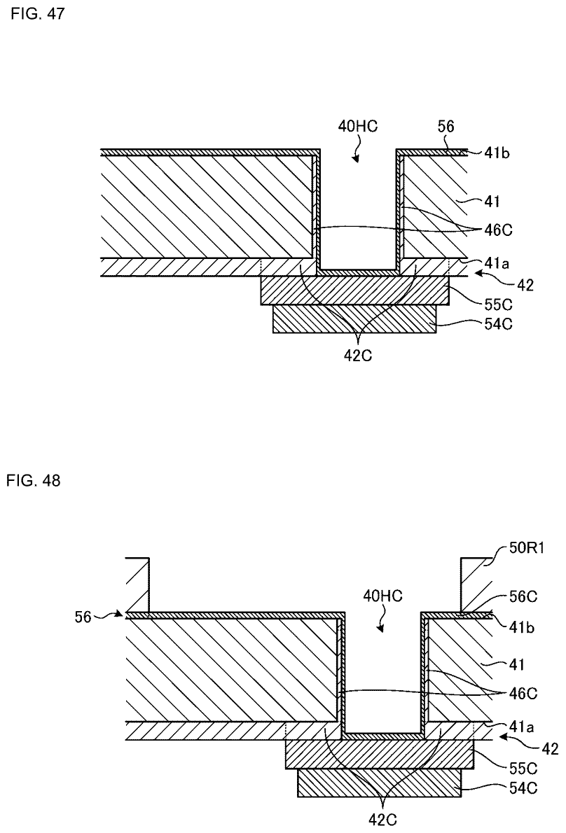

FIG. 47 is a schematic cross-sectional view for explaining the seed layer forming process according to the second example embodiment. As illustrated in FIG. 47, in the seed layer forming process, similarly to the first example embodiment, a seed layer 56C is formed by, for example, sputtering or the like.

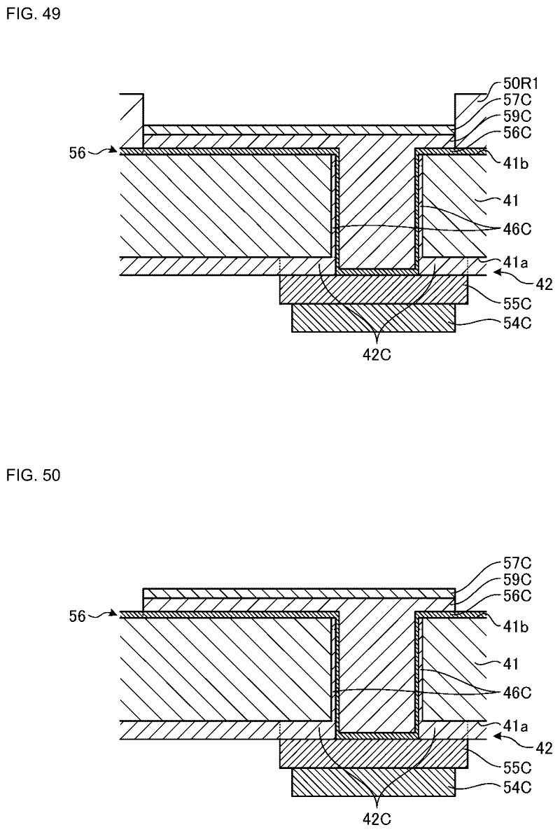

FIGS. 48 to 50 are cross-sectional views for explaining the through electrode forming process according to the second example embodiment. In the through electrode forming process, similarly to the first example embodiment, patterning is performed with the plating resist 50R1 as illustrated in FIG. 48, the through via 59C and the second land 57A are formed as illustrated in FIG. 49, and the plating resist 50R1 is removed as illustrated in FIG. 50. As a result, the second land 57C is laminated on the second main surface 41b of the second substrate 41 without an insulator interposed therebetween.

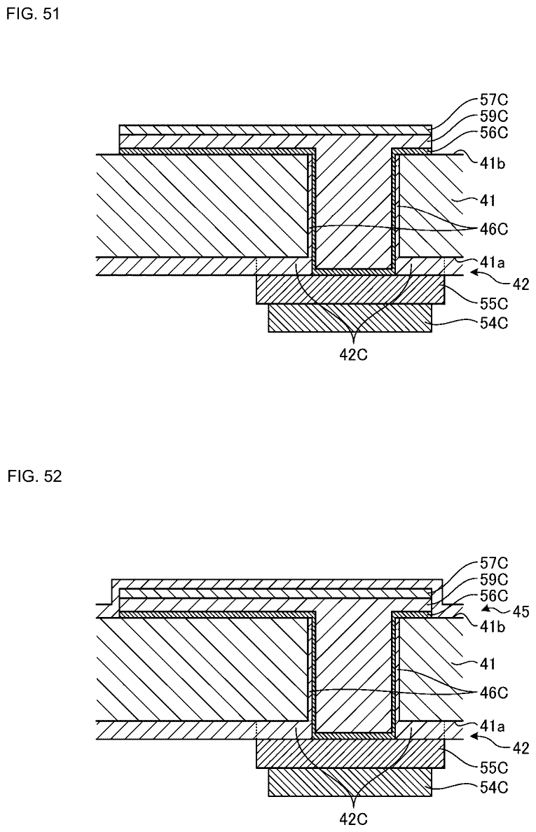

FIG. 51 is a cross-sectional view for explaining the seed layer removal process according to the second example embodiment. As illustrated in FIG. 51, in the seed layer removal process, similarly to the first example embodiment, the seed layer 56 except for a portion of the seed layer 56C that overlaps the second land 57C in plan view is removed.

FIG. 52 is a cross-sectional view for explaining the third insulator forming process according to the second example embodiment. As illustrated in FIG. 52, in the third insulator forming process, similarly to the first example embodiment, the insulator 45 on the second main surface 41b of the second substrate 41 is additionally formed by, for example, the chemical vapor deposition method or the like and the insulator 45 is formed on the second land 57C.

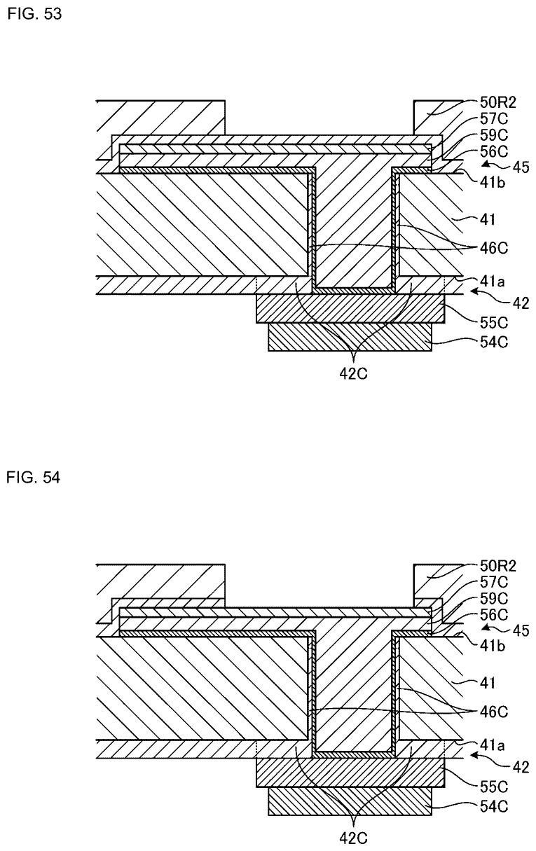

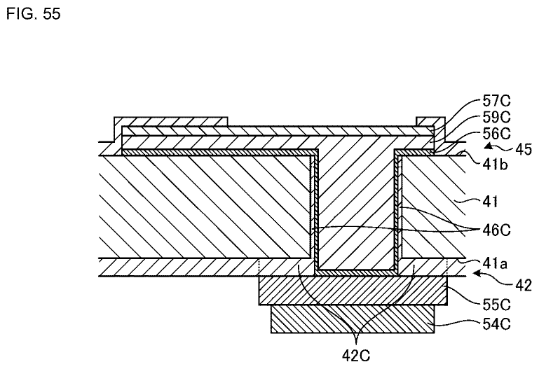

FIGS. 53 to 55 are cross-sectional views for explaining the bump forming process according to the second example embodiment. As illustrated in FIGS. 53 to 55, in the bump forming process, similarly to the first example embodiment, patterning is performed with the resist 50R2 as illustrated in FIG. 53, a portion of the insulator 45 is removed as illustrated in FIG. 54, and the resist 50R2 is removed as illustrated in FIG. 55. As a result, a portion of the second land 57C is exposed. After that, the bump 58C is formed on the surface exposed by the second land 57C.

With the above processes, the extraction electrode 50CA that is connected to the reference potential can be manufactured. In the second example embodiment, other extraction electrodes that are connected to the reference potential are also manufactured by the same or substantially the same method.

With the above processes, the acoustic wave device according to the second example embodiment can be manufactured. Accordingly, in the acoustic wave device, the insulator can be eliminated only between the extraction electrode 50CA and the second main surface 41b of the second substrate 41, and thus the inductance L1 of the extraction electrode 50CA connected to the reference potential can be reduced, and the out-of-band attenuation can be reduced. The method of manufacturing the acoustic wave device according to the second example embodiment described above is merely an example, and the present disclosure is not limited thereto. For example, similarly to the first example embodiment, there is a possibility that the third insulator forming process is not performed, and the bump 58C may be formed on the second land 57C after the seed removal process.

As described above, in the method of manufacturing an acoustic wave device according to the second example embodiment, in the insulator removal process, a portion of the second main surface 41b of the second substrate 41 is further exposed in plan view, and in the through electrode forming process, at least one second land 57C is formed on the second main surface 41b of the second substrate 41 without an insulator interposed therebetween. Accordingly, the insulator can be eliminated only between the extraction electrode 50CA and the second main surface 41b of the second substrate 41, and thus the inductance L1 of the extraction electrode 50CA connected to the reference potential can be reduced, and the out-of-band attenuation can be reduced.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a first substrate;
a piezoelectric layer overlapping the first substrate in plan view and including a first main surface and a second main surface on an opposite side of the first main surface;
a functional electrode on at least one of the first main surface of the piezoelectric layer and the second main surface of the piezoelectric layer;
a second substrate including a first main surface facing the first main surface of the piezoelectric layer in a first direction and a second main surface on an opposite side; and
a plurality of extraction electrodes including a support portion supporting the second substrate between the first main surface of the piezoelectric layer and the first main surface of the second substrate, a through via penetrating the second substrate, a first land on the first main surface of the second substrate and electrically connected to the through via, and a second land on the second main surface of the second substrate and electrically connected to the through via; wherein
in at least one of the plurality of extraction electrodes, insulators are provided between the first main surface of the second substrate and the first land, between the second main surface of the second substrate and the second land, and between a side wall of the through via and the second substrate.

2. The acoustic wave device according to claim 1, wherein the second substrate is a silicon substrate.

3. The acoustic wave device according to claim 1, wherein an extraction electrode of the plurality of extraction electrodes is connected to a reference potential and includes no insulator at least at a portion between the first main surface of the second substrate and the first land.

4. The acoustic wave device according to claim 1, wherein an extraction electrode of the plurality of extraction electrodes is connected to a reference potential and includes no insulator at least at a portion between the second main surface of the second substrate and the second land.

5. The acoustic wave device according to claim 1, wherein an extraction electrode of the plurality of extraction electrodes is connected to a reference potential and includes no insulator at least at a portion between the side wall of the through via and the second substrate.

6. The acoustic wave device according to claim 1, wherein, in all of the plurality of extraction electrodes, the insulators are provided between the first main surface of the second substrate and the first land, between the second main surface of the second substrate and the second land, and between the side wall of the through via and the second substrate.

7. The acoustic wave device according to claim 1, wherein the functional electrode includes one or more first electrode fingers extending in a second direction intersecting with the first direction, and one or more second electrode fingers facing one of the one or more first electrode fingers in a third direction orthogonal or substantially orthogonal to the second direction and extending in the second direction.

8. The acoustic wave device according to claim 7, wherein a thickness of the piezoelectric layer is about 2p or less, where p is a center-to-center distance between the first electrode finger and the second electrode finger adjacent to each other, in the one or more first electrode fingers and the one or more second electrode fingers.

9. The acoustic wave device according to claim 7, wherein the piezoelectric layer includes lithium niobate or lithium tantalate.

10. The acoustic wave device according to claim 7, wherein the acoustic wave device is structured to generate a bulk wave in a thickness slip mode.

11. The acoustic wave device according to claim 7, wherein d/p is about 0.5 or less, where d is a thickness of the piezoelectric layer, and p is a center-to-center distance between the first electrode finger and the second electrode finger adjacent to each other, in the one or more first electrode fingers and the one or more second electrode fingers.

12. The acoustic wave device according to claim 11, wherein d/p is about 0.24 or less.

13. The acoustic wave device according to claim 7, wherein MR≤about 1.75 (d/p)+0.075, where an excitation region is a region in which the first electrode fingers and the second electrode fingers adjacent to each other overlap each other when viewed in a facing direction, and MR is a metallization ratio of the one or more first electrode fingers and the one or more second electrode fingers to the excitation region.

14. The acoustic wave device according to claim 7, wherein the acoustic wave device is structured to generate a plate wave.

15. The acoustic wave device according to claim 1, wherein
the piezoelectric layer is lithium niobate or lithium tantalate, and Euler angles (φ, θ, ψ) of the lithium niobate or lithium tantalate are within a range of Formula (1), Formula (2), or Formula (3):
(0°±10°,0° to 20°,any ψ) Formula (1);
(0°±10°,20° to 80°,0° to 60°(1−(θ−50)²/900)^{1/2})or(0°±10°,20° to 80°,[180°−60°(1−(θ−50)²/900)^{1/2}] to 180°) Formula (2); and
(0°±10°,[180°−30°(1−(ψ−90)²/8100)^{1/2}] to 180°,any ψ) Formula (3).

16. A method of manufacturing an acoustic wave device, the method comprising:
laminating a piezoelectric layer including a first main surface and a second main surface on an opposite side of the first main surface, and a functional electrode provided on at least one of the first main surface and the second main surface of the piezoelectric layer, in a first direction on a first substrate;
laminating a first insulator and a first land on a first main surface of a second substrate including the first main surface and a second main surface on an opposite side of the first main surface;
bonding the first substrate and the second substrate such that the first main surface of the piezoelectric layer and the first main surface of the second substrate face each other;
forming a second insulator on at least a portion of the second main surface of the second substrate;
forming a through-hole that penetrates the second substrate at a position that overlaps the first land in plan view;
forming a third insulator on a second main surface of the second substrate, a side wall of the through-hole, and a surface of the first land exposed to the through-hole;
removing a portion of the third insulator formed in the forming the third insulator; and
forming a through via and a second land in the through-hole and the second main surface of the second substrate after the removing the portion of the third insulator; wherein
in the laminating the first insulator and the first land, the first land is laminated on the first main surface of the second substrate with the first insulator interposed therebetween;
in the removing the portion of the third insulator, at least a portion of a surface of the first land on a second substrate side at a position that overlaps the through-hole is exposed in plan view; and
in the forming the through via and the second land, at least one second land is formed on the second main surface of the second substrate with the third insulator interposed therebetween.

17. The method of manufacturing an acoustic wave device according to claim 16, wherein
in the removing the portion of the third insulator, a portion of the second main surface of the second substrate is further exposed in plan view; and
in the forming the through via and the second land, at least one second land is formed on the second main surface of the second substrate without an insulator interposed therebetween.

18. The method of manufacturing an acoustic wave device according to claim 16, wherein the second substrate is a silicon substrate.

19. The method of manufacturing an acoustic wave device according to claim 16, wherein the piezoelectric layer includes lithium niobate or lithium tantalate.
